(19) United States
(12) Patent Application Publication
(10) Pub. No.: US 2026/0344485 A1
(43) Pub. Date: Oct. 29, 2026

(54) SYSTEMS FOR IMPROVED PLACEMENT OF REDISTRIBUTION LAYERS IN MULTI-DIE PACKAGES AND METHODS OF FORMING THE SAME

(71) Applicant: Taiwan Semiconductor Manufacturing Company Limited, Hsinchu (TW)

(72) Inventors: Jhih-Yu Wang, New Taipei City (TW); Po-Han Wang, Hsinchu City (TW); Yu-Hsiang Hu, Hsinchu City (TW); Hung-Jui Kuo, Hsinchu City (TW)

(21) Appl. No.: 19/736,268

(22) Filed: Jul. 9, 2026

Related U.S. Application Data
(62) Division of application No. 18/402,778, filed on Jan. 3, 2024.
(60) Provisional application No. 63/613,069, filed on Dec. 21, 2023.

(51) Int. Cl. H10W 70/685; H10W 20/20; H10W 46/00; H10W 90/00; H10W 74/00; H10W 74/15

(52) U.S. Cl. CPC H10W 70/685; H10W 20/20; H10W 46/00; H10W 90/00; H10W 46/301; H10W 74/00; H10W 74/15; H10W 90/724; H10W 90/734

(57) ABSTRACT

An embodiment semiconductor package structure may include a first redistribution layer and a first semiconductor die attached to the first redistribution layer. The first semiconductor die may include first front-side electrical contacts and first back-side electrical contacts such that the first front-side electrical contacts are electrically connected to the first redistribution layer. The semiconductor package structure may further include a second redistribution layer formed over the first semiconductor die such that the second redistribution layer is electrically connected to the first back-side electrical contacts of the first semiconductor die and to a second semiconductor die attached to the second redistribution layer and positioned vertically over the first semiconductor die. The first semiconductor die may include at least two alignment marks separated by at least 50 microns. An overlay error between alignment of the first semiconductor die and the second redistribution layer may be less than or equal to 0.5 microns.

### RELATED APPLICATIONS

This application is a divisional of U.S. Patent Application No. 18/402,778 entitled “Systems for Improved Placement of Redistribution Layers in Multi-Die Packages and Methods of Forming the Same,” filed Jan. 3, 2024, which claims the benefit of priority from U.S. Provisional Application Serial No. 63/613,069, entitled “Systems For Improved Placement Of Redistribution Layers In Multi-Die Packages And Methods Of Forming The Same,” filed on Dec. 21, 2023, the entire contents of both of which are incorporated herein in their entirety by reference for all purposes.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers over a semiconductor substrate, and patterning the various material layers using lithography and etching to form circuit components and elements thereon. Dozens, hundreds, or thousands of integrated circuits are typically manufactured on a single semiconductor wafer. Individual dies on the wafer may be singulated by sawing between the integrated circuits along scribe lines. The individual dies are typically packaged separately, in multi-chip modules, or in other types of packaging, for example.

As semiconductor packages have become more complex, package sizes have tended to become larger to accommodate greater numbers of integrated circuits and/or dies per package. These larger and more complex semiconductor packages have created challenges in making effective and reliable interconnections among various components of the semiconductor package. As such, there is an ongoing need for improvements to semiconductor package designs with an emphasis on reducing interconnect lengths to thereby reduce ohmic loss, heat generation, and signal delay. One promising approach includes forming semiconductor packages by vertically stacking semiconductor dies. The semiconductor dies may include alignment marks that allow for increasingly precise placement of the semiconductor dies and redistribution layers within the semiconductor package as they are stacked.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a semiconductor package structure, according to various embodiments.

FIG. 2A is a vertical cross-sectional view of an intermediate structure after formation of complementary metal-oxide-semiconductor (CMOS) transistors, metal interconnect structures, and dielectric material layers, according to various embodiments.

FIG. 2B is a vertical cross-sectional view of a further intermediate structure during formation of a front-side interconnect structure, according to various embodiments.

FIG. 3A is a vertical cross-sectional view of an intermediate structure that may be used in the formation of devices on a semiconductor wafer, according to various embodiments.

FIG. 3B is a vertical cross-sectional view of a further intermediate structure that may be used in the formation of devices on a semiconductor wafer, according to various embodiments.

FIG. 3C is a vertical cross-sectional view of a further intermediate structure that may be used in the formation of devices on a semiconductor wafer, according to various embodiments.

FIG. 3D is a vertical cross-sectional view of a further intermediate structure that may be used in the formation of devices on a semiconductor wafer, according to various embodiments.

FIG. 4A is a vertical cross-sectional view of an intermediate structure that may be used in the formation of a semiconductor package structure, according to various embodiments.

FIG. 4B is a vertical cross-sectional view of a further intermediate structure that may be used in the formation of a semiconductor package structure, according to various embodiments.

FIG. 4C is a vertical cross-sectional view of a further intermediate structure that may be used in the formation of a semiconductor package structure, according to various embodiments.

FIG. 4D is a vertical cross-sectional view of a further intermediate structure that may be used in the formation of a semiconductor package structure, according to various embodiments.

FIG. 4E is a vertical cross-sectional view of a further intermediate structure that may be used in the formation of a semiconductor package structure, according to various embodiments.

FIG. 4F is a vertical cross-sectional view of a further intermediate structure that may be used in the formation of a semiconductor package structure, according to various embodiments.

FIG. 4G is a vertical cross-sectional view of a further intermediate structure that may be used in the formation of a semiconductor package structure, according to various embodiments.

FIG. 4H is a vertical cross-sectional view of a further intermediate structure that may be used in the formation of a semiconductor package structure, according to various embodiments.

FIG. 4I is a vertical cross-sectional view of a further intermediate structure that may be used in the formation of a semiconductor package structure, according to various embodiments.

FIG. 4J is a vertical cross-sectional view of a further intermediate structure that may be used in the formation of a semiconductor package structure, according to various embodiments.

FIG. 4K is a vertical cross-sectional view of a further intermediate structure that may be used in the formation of a semiconductor package structure, according to various embodiments.

FIG. 4L is a vertical cross-sectional view of a further intermediate structure that may be used in the formation of a semiconductor package structure, according to various embodiments.

FIG. 4M is a vertical cross-sectional view of a further intermediate structure that may be used in the formation of a semiconductor package structure, according to various embodiments.

FIG. 4N is a vertical cross-sectional view of a further intermediate structure that may be used in the formation of a semiconductor package structure, according to various embodiments.

FIG. 5A is a top view of a wafer-level structure that may be used in the formation of a plurality of semiconductor package structures, according to various embodiments.

FIG. 5B is a top view of a further wafer-level structure that may be used in the formation of a plurality of semiconductor package structures, according to various embodiments.

FIG. 5C is a top view of a further wafer-level structure illustrating placement errors, according to various embodiments.

FIG. 5D is an expanded top view of a portion of the wafer-level structure of FIG. 5C, according to various embodiments.

FIG. 5E is a top view of a further wafer-level structure that may be used in the formation of a plurality of semiconductor package structures, according to various embodiments.

FIG. 5F is an expanded top view of a portion of the wafer-level structure of FIG. 5E, according to various embodiments.

FIG. 6A is a top view of a configuration including a semiconductor die having back-side electrical contacts and alignment marks, according to various embodiments.

FIG. 6B is a top view of a further configuration including two semiconductor dies that each have back-side electrical contacts and alignment marks, according to various embodiments.

FIG. 6C is a top view of a further configuration including three semiconductor dies that each have back-side electrical contacts and alignment marks, according to various embodiments.

FIG. 7A is a vertical cross-sectional view of a semiconductor die that includes back-side electrical contacts and alignment marks, according to various embodiments.

FIG. 7B is a vertical cross-sectional view of a portion of the semiconductor die of FIG. 7A showing details of an alignment mark, according to various embodiments.

FIG. 8A is a top view of an alignment mark formed of a plurality of via structures, according to various embodiments.

FIG. 8B is a top view of a further alignment mark formed of a plurality of via structures, according to various embodiments.

FIG. 8C is a top view of a further alignment mark formed of a plurality of via structures, according to various embodiments.

FIG. 8D is a top view of a further alignment mark formed of a plurality of via structures, according to various embodiments.

FIG. 8E is a top view of a further alignment mark formed of a plurality of via structures, according to various embodiments.

FIG. 8F is a top view of a further alignment mark formed of a plurality of via structures, according to various embodiments.

FIG. 9 is a flowchart illustrating operations of a method of forming wafer-level semiconductor structure, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The various embodiments disclosed herein may be advantageous by providing systems and methods to improve accuracy of placement of various components (e.g., semiconductor dies) of a semiconductor package. In this regard, a semiconductor package may be formed by attaching semiconductor dies over a first redistribution layer and forming a second redistribution layer over the semiconductor dies. Embodiment systems and methods provide alignment marks having detailed features that allow precise measurement of placement errors of the semiconductor dies. Such measurements may then be used to adjust features of the second redistribution layer to correct for placement errors of the semiconductor dies.

An embodiment semiconductor package structure may include a first redistribution layer and a first semiconductor die attached to the first redistribution layer. The first semiconductor die may include first front-side electrical contacts and first back-side electrical contacts such that the first front-side electrical contacts are electrically connected to the first redistribution layer. The semiconductor package structure may further include a second redistribution layer formed over the first semiconductor die such that the second redistribution layer is electrically connected to the first back-side electrical contacts of the first semiconductor die and to a second semiconductor die attached to the second redistribution layer and positioned vertically over the first semiconductor die. The first semiconductor die may include at least two alignment marks separated by at least 50 microns. An overlay error between alignment of the first semiconductor die and the second redistribution layer may be less than or equal to 0.5 microns.

An embodiment wafer-level semiconductor structure may include a first redistribution layer formed over a wafer such that the first redistribution layer includes a first plurality of repeat units that are spatially displaced from one another. The wafer-level semiconductor structure may further include a first semiconductor die and a second semiconductor die electrically coupled to the first redistribution layer over each of the first plurality of repeat units and a second redistribution layer formed over, and electrically coupled to, the first semiconductor die and the second semiconductor die. The second redistribution layer may include a second plurality of repeat units that are spatially displaced from one another. Further, each of the second plurality of repeat units may spatially aligned with a respective area associated with the first semiconductor die and the second semiconductor die such that an overlay error is less than or equal to 0.5 microns.

An embodiment method of forming a wafer-level semiconductor structure may include forming a first redistribution layer over a wafer such that the first redistribution layer includes a first plurality of repeat units that are spatially displaced from one another. The method may further include attaching a first semiconductor die and a second semiconductor die to the first redistribution layer over each of the first plurality of repeat units such that each of the first semiconductor die and the second semiconductor die are electrically coupled to the first redistribution layer. The method may further include measuring a spatial position and orientation of a first alignment mark formed on the first semiconductor die and of a second alignment mark formed on the second semiconductor die and determining a spatial position and orientation of a respective area associated with the first semiconductor die and the second semiconductor die based on the spatial position and orientation of the first alignment mark and the second alignment mark. The method may further include forming a second redistribution layer over, and electrically attached to, the first semiconductor die and the second semiconductor die by performing various additional operations.

The additional operation may include forming a second plurality of repeat units that are spatially displaced from one another such that each repeat unit includes redistribution layer electrical connections. The method may further include spatially aligning each of the second plurality of repeat units with the respective area associated with the first semiconductor die and the second semiconductor die based on the spatial position and orientation of the respective area associated with the first semiconductor die and the second semiconductor die. The method may further include electrically connecting the redistribution layer electrical connections to semiconductor die electrical connections formed on the first semiconductor die and the second semiconductor die.

As used herein, a “back-end-of-line” component or a “BEOL” component refers to any component that is formed at a contact level or at a metal interconnect level. A “metal interconnect level” refers to a level through which a metal interconnect structure such as a metal line or a metal via structure vertically extends. As used herein, a “front-end-of-line” component or an “FEOL” component refers to any component that is formed prior to formation of any contact level structure, if followed by formation of contact level structures, or without formation of any contact level structure or any metal interconnect structure (i.e., not followed by formation of any contact level structure or any metal interconnect structure).

In general, FEOL components refer to semiconductor device components that may be formed during a CMOS manufacturing process prior to formation of any contact via structure on nodes of field effect transistors, and BEOL components refer to semiconductor device components that may be formed during a CMOS manufacturing process during, or after, the earliest contact via formation process that forms contact via structures on nodes of field effect transistors. In embodiments in which any embodiment manufacturing steps are integrated into a CMOS manufacturing process, a component formed prior to formation of any contact via structure on nodes of field effect transistors may be referred to as an FEOL component, and a component formed during, or after, the earliest contact via formation process that forms contact via structures on nodes of field effect transistors may be referred to as a BEOL component.

Generally, an FEOL component may be formed within a semiconductor substrate, directly on a semiconductor substrate, or indirectly on a semiconductor substrate without any intervening metal interconnect structure between the semiconductor substrate and the component. Examples of the FEOL components include planar field effect transistors using a portion of the semiconductor substrate as a portion of a channel, fin field effect transistors (FinFET), gate-all-around field effect transistors, and any device component that includes a portion of a semiconductor substrate that has a lateral extent greater than the lateral extent of the respective device component. Typically, for each FEOL component, no metal interconnect structure vertically extends from a first horizontal plane including a top surface of the FEOL component to a second horizontal plane including a bottom surface of the FEOL component, or the FEOL component contacts, or is laterally surrounded by, a semiconductor material layer having a greater lateral extent than the FEOL component.

Examples of the BEOL components may include any dielectric material layer having formed therein a metal via structure or having formed therein a metal line structure, any metal interconnect structure, memory cells formed without using any portion of a semiconductor substrate, selector cells formed without using any portion of a semiconductor substrate, thin film transistors formed without using any portion of a semiconductor substrate (but may include patterned semiconductor material portions having a lateral extent that does not exceed the lateral extent of an individual thin film transistor or a cluster of merged thin film transistors), and bonding pads. Typically, for each BEOL component, at least one metal interconnect structure vertically extends from a first horizontal plane including a top surface of the BEOL component to a second horizontal plane including a bottom surface of the BEOL component, and the BEOL component does not contact, and is not laterally surrounded by, a semiconductor material layer having a greater lateral extent than the BEOL component.

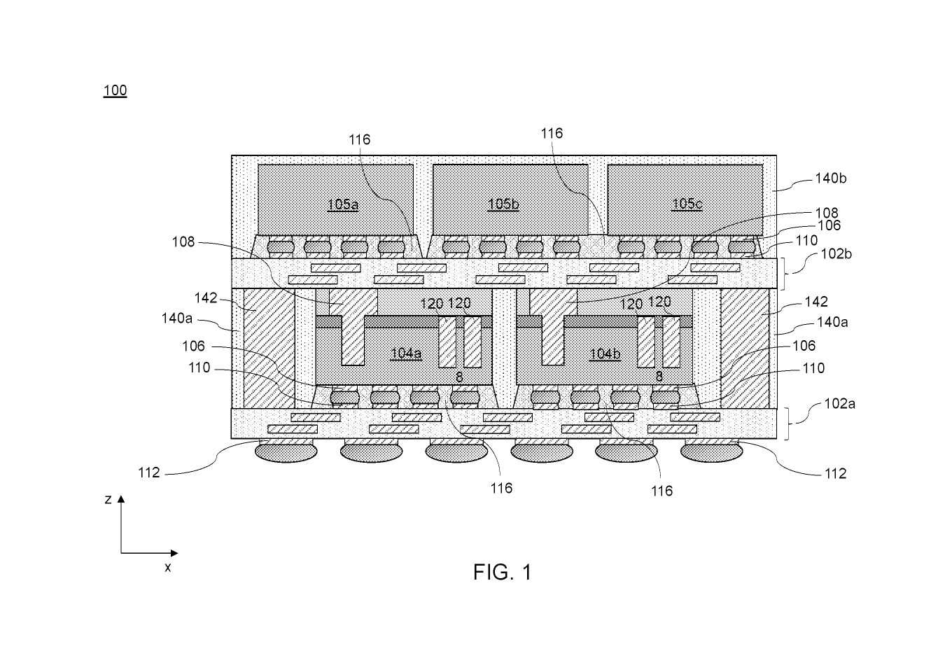

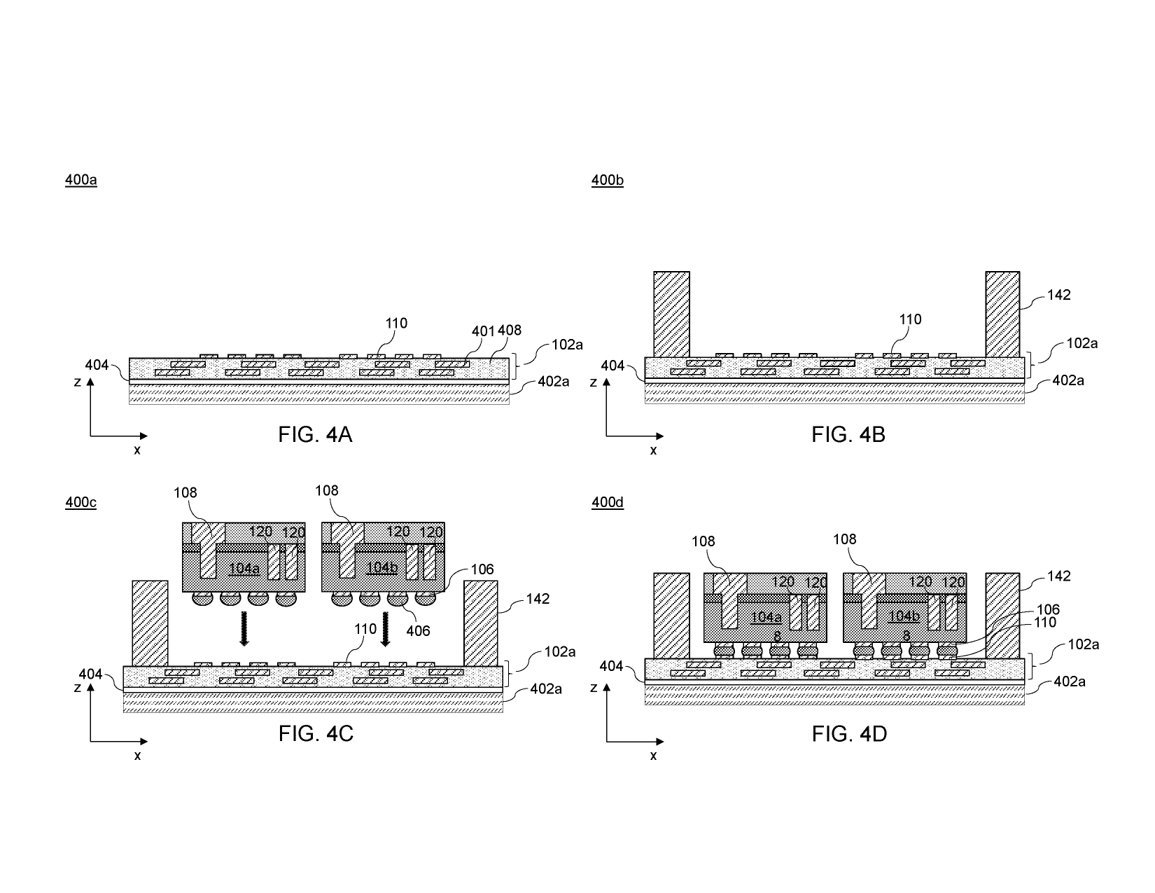

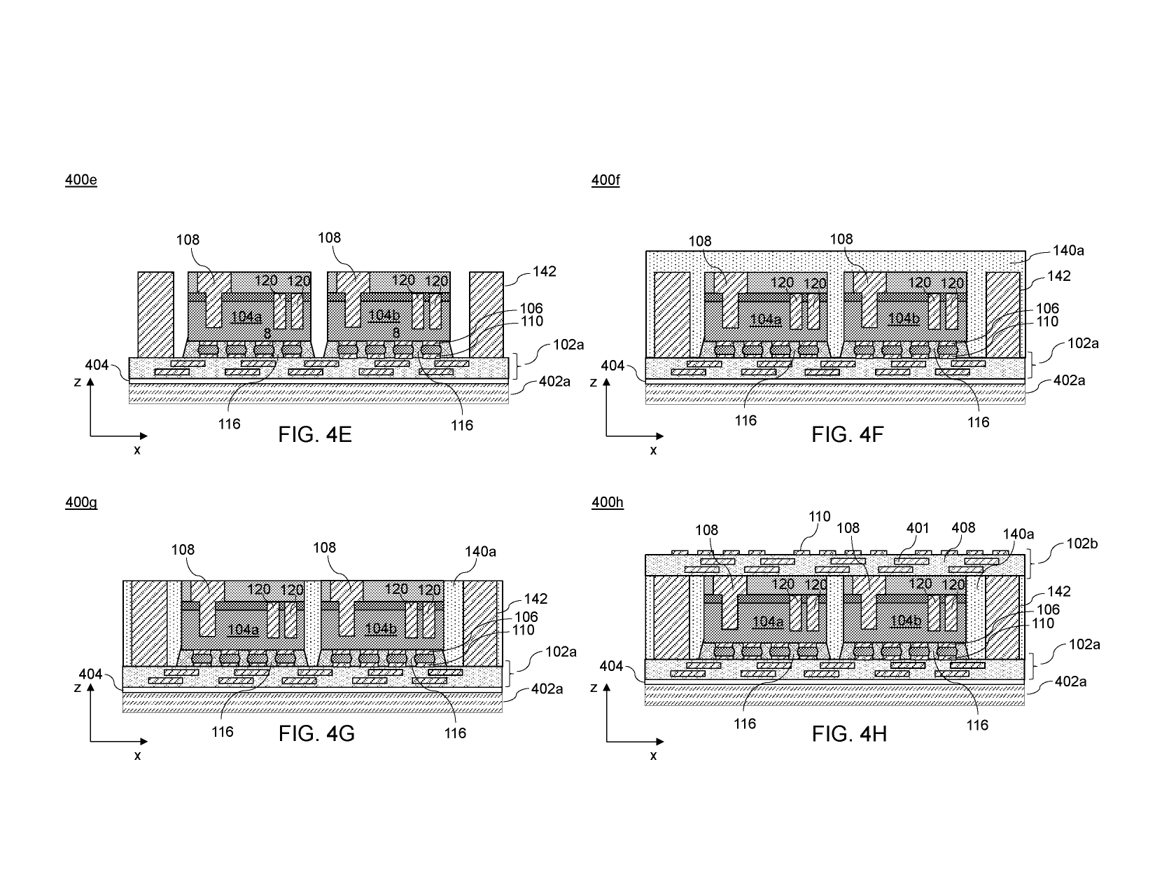

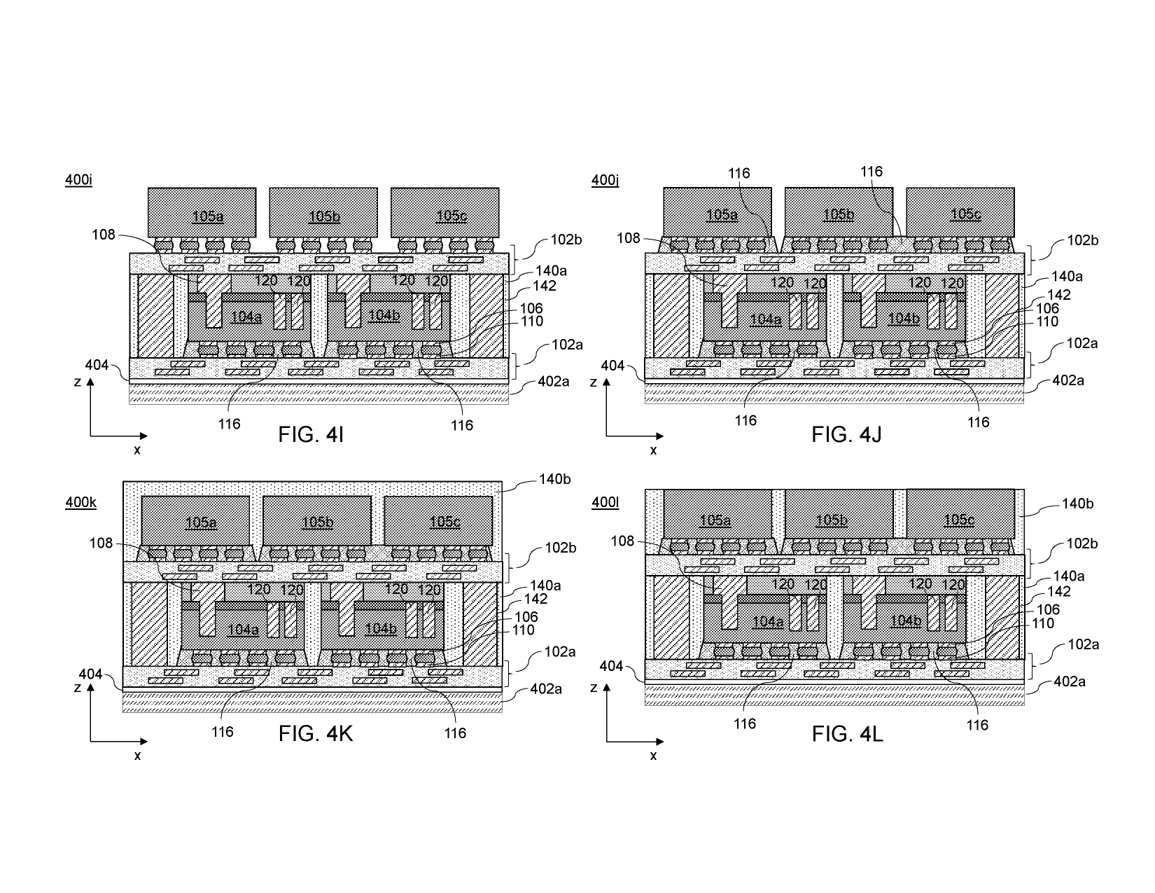

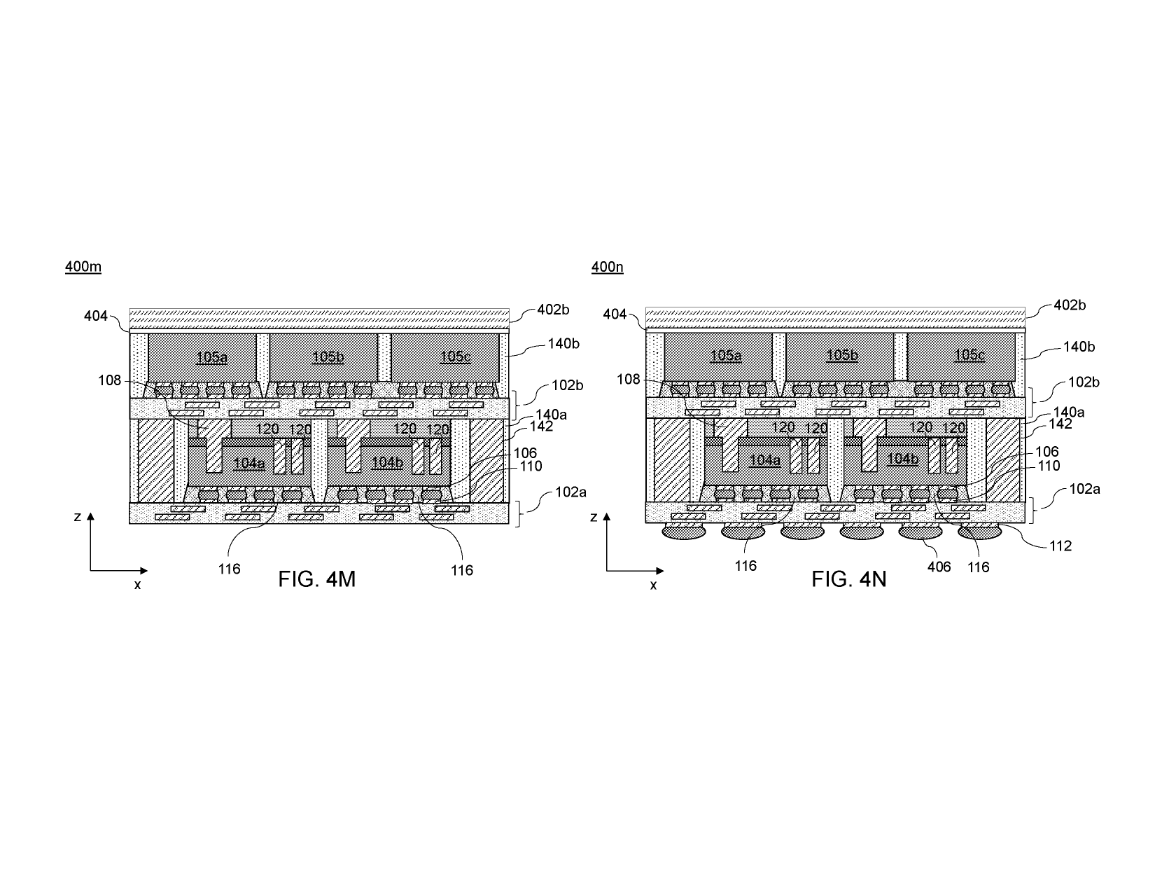

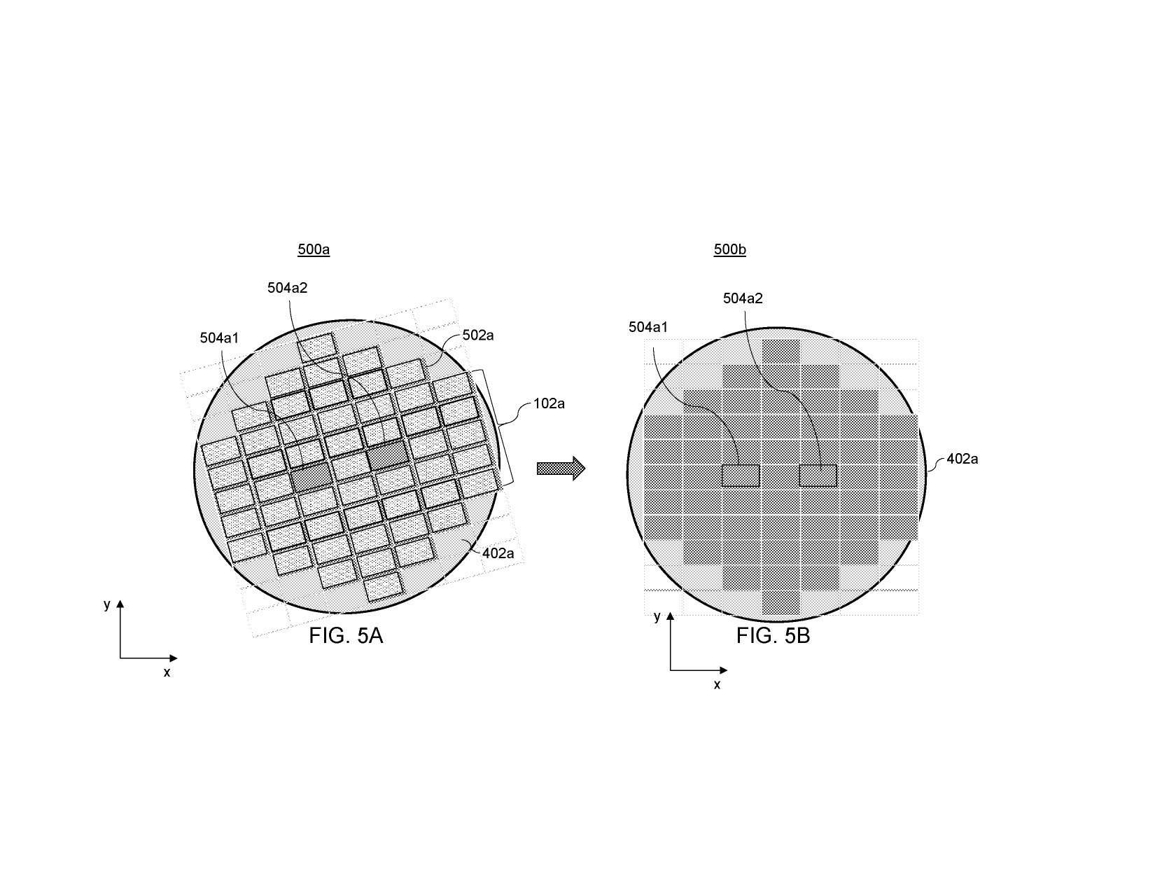

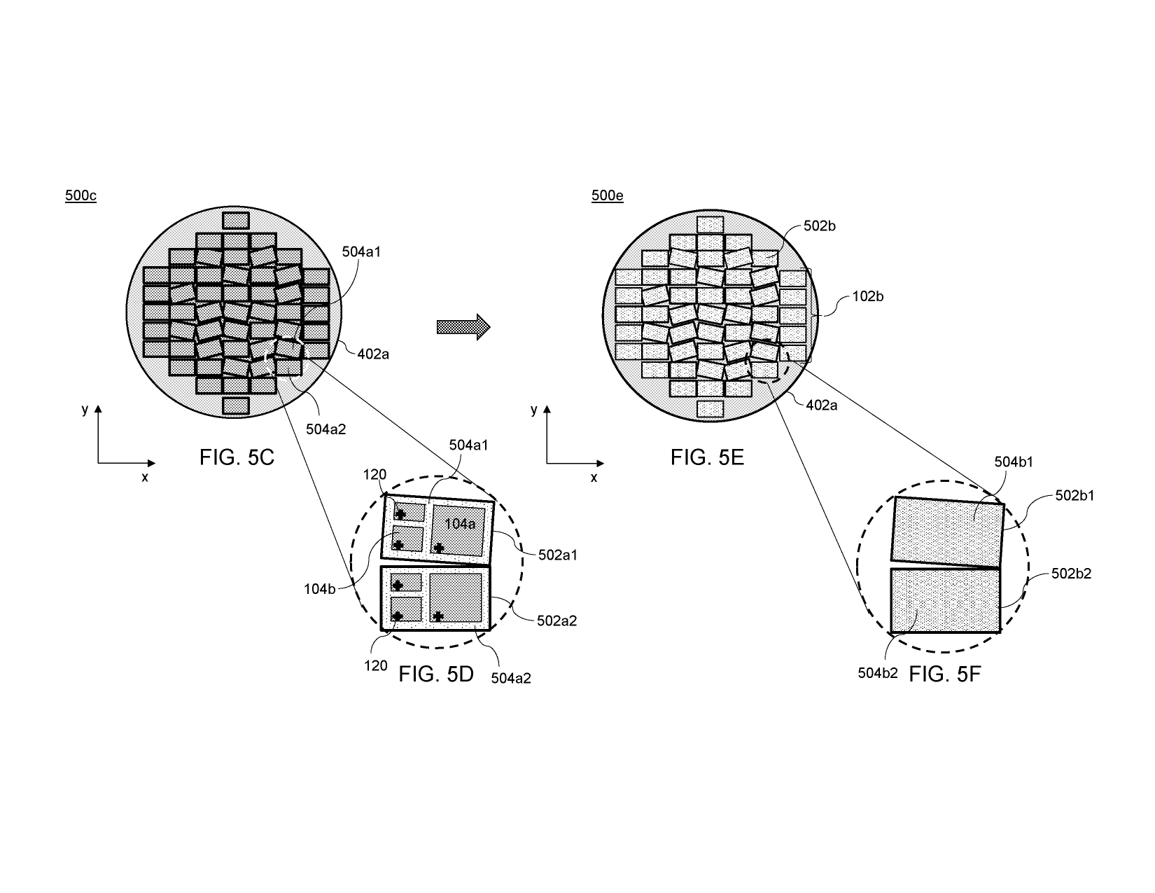

FIG. 1 is a vertical cross-sectional view of a semiconductor package structure 100, according to various embodiments. As described in greater detail with reference to FIGS. 4A to 5F, below, the semiconductor package structure 100 may be formed by performing a wafer-level process in which a plurality of similar semiconductor package structures 100 may be formed on a wafer. The wafer 402 may be diced to yield a plurality of similar semiconductor package structures 100. The semiconductor package structure 100 may include a first redistribution layer 102a and a second redistribution layer 102b.

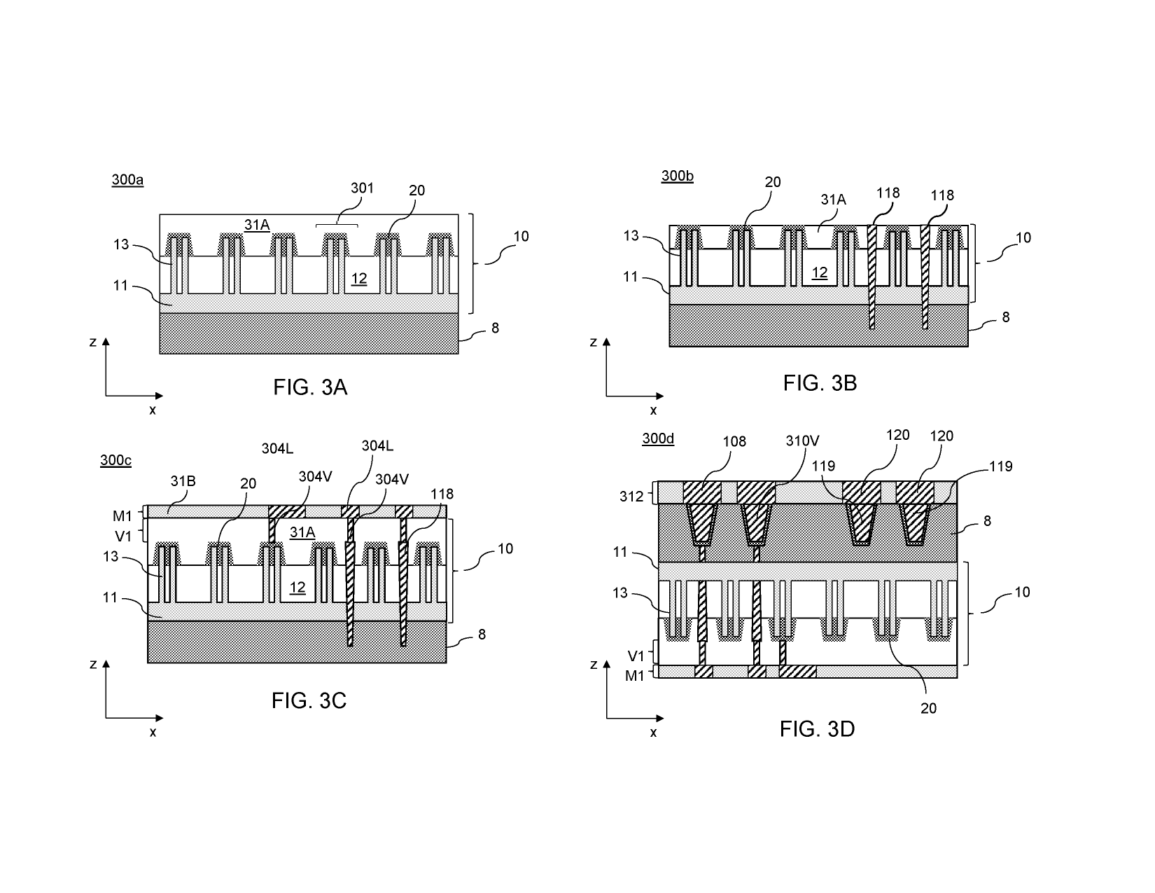

The semiconductor package structure 100 may further include a first semiconductor die 104a and a second semiconductor die 104b electrically coupled to the first redistribution layer 102a. As described with reference to FIGS. 3A to 3D, below, the first semiconductor die 104a and the second semiconductor die 104b may include front-side electrical contacts 106 and back-side electrical contacts 108. As shown, the front-side electrical contacts 106 may be electrically coupled to the first redistribution layer 102a and the back-side electrical contacts 108 may be electrically connected to the second redistribution layer 102b.

The first redistribution layer 102a may include top-side electrical contacts 110 and bottom-side electrical contacts 112. A first size and spacing of the top-side electrical contacts 110 may be smaller than a second size and spacing of the bottom-side electrical contacts 112. As such, the first redistribution layer 102a may have a fan-out configuration. In this regard, the first semiconductor die 104a and the second semiconductor die 104b may be formed separately and may be attached to the first redistribution layer 102a using a flip-chip bonding process. The smaller size and spacing of the top-side electrical contacts 110 may accommodate bonding to the front-side electrical contacts 106 of the first semiconductor die 104a and the second semiconductor die 104b while the larger size and spacing of the bottom-side electrical contacts 112 may be configured for bonding the semiconductor package structure 100 to a support structure, such as a printed circuit board (not shown).

The semiconductor package structure 100 may further include a first molding material 140a formed around the first semiconductor die 104a and the second semiconductor die 104b. The first molding material 140a may be further mechanically attached to the first redistribution layer 102a and the second redistribution layer 102b and may provide mechanical support for the semiconductor package structure 100. As shown in FIG. 1, the semiconductor package structure 100 may include through-molding-material vias 142. The through-molding-material vias 142 may provide direct electrical connections between the first redistribution layer 102a and the second redistribution layer 102b. The through-molding-material vias 142 may be formed according to processes described in greater detail with reference to FIG. 4B, below.

As shown in FIG. 1, the semiconductor package structure 100 may further include one or more additional semiconductor dies (105a, 105b, 105c) that may be electrically coupled to the second redistribution layer 102b. In this regard, the semiconductor package structure 100 may include a third semiconductor die 105a, a fourth semiconductor die 105b, and a fifth semiconductor die 105c formed over, and electrically attached to, the second redistribution layer 102b. As such, the semiconductor package structure 100 may be configured as a three-dimensional integrated circuit having a plurality of semiconductor dies (104a, 104b, 105a, 105b, 105c) configured in a vertically stacked structure.

The various semiconductor dies (104a, 104b, 105a, 105b, 105c) may be configured to provide respective functionalities. For example, according to some embodiments, the first semiconductor die 104a and the second semiconductor die 104b may be logic dies, system-on-chip dies, etc., that provide a first functionality. Similarly, the additional semiconductor dies (105a, 105b, 105c) may provide a second functionality. In this regard, the additional semiconductor dies (105a, 105b, 105c) may be configured as memory dies. In various embodiments, the additional semiconductor dies (105a, 105b, 105c) may each provide the same functionality. Alternatively, each of the additional semiconductor dies (105a, 105b, 105c) may provide different respective functionalities (e.g., various levels of memory).

As shown, each of the additional semiconductor dies (105a, 105b, 105c) may include front-side electrical contacts 106 that may be electrically connected to top-side electrical contacts 110 of the second redistribution layer 102b. In various embodiments, the additional semiconductor dies (105a, 105b, 105c) may be single-sided dies having only front-side electrical contacts 106. In other embodiments, the additional semiconductor dies (105a, 105b, 105c) may further include back-side electrical contacts (not shown) that may allow the additional semiconductor dies (105a, 105b, 105c) to be electrically connected to additional circuit components to be subsequently formed above the additional semiconductor dies (105a, 105b, 105c).

The semiconductor package structure 100 may further include a second molding material 140b formed around the third semiconductor die 105a, the fourth semiconductor die 105b, and the fifth semiconductor die 105c. The second molding material 140b may be mechanically attached to the second redistribution layer 102b and may provide additional mechanical support for the semiconductor package structure 100. As shown, the semiconductor package structure 100 may further include an underfill material 116 formed in spaces between the semiconductor dies (104a, 104b, 105a, 105b, 105c) and respective surfaces of the first redistribution layer 102a and the second redistribution layer 102b. The underfill material 116 may be formed prior to formation of the respective first molding material 140a and the second molding material 140b, as described in greater detail below (e.g., see FIGS. 4E and 4F).

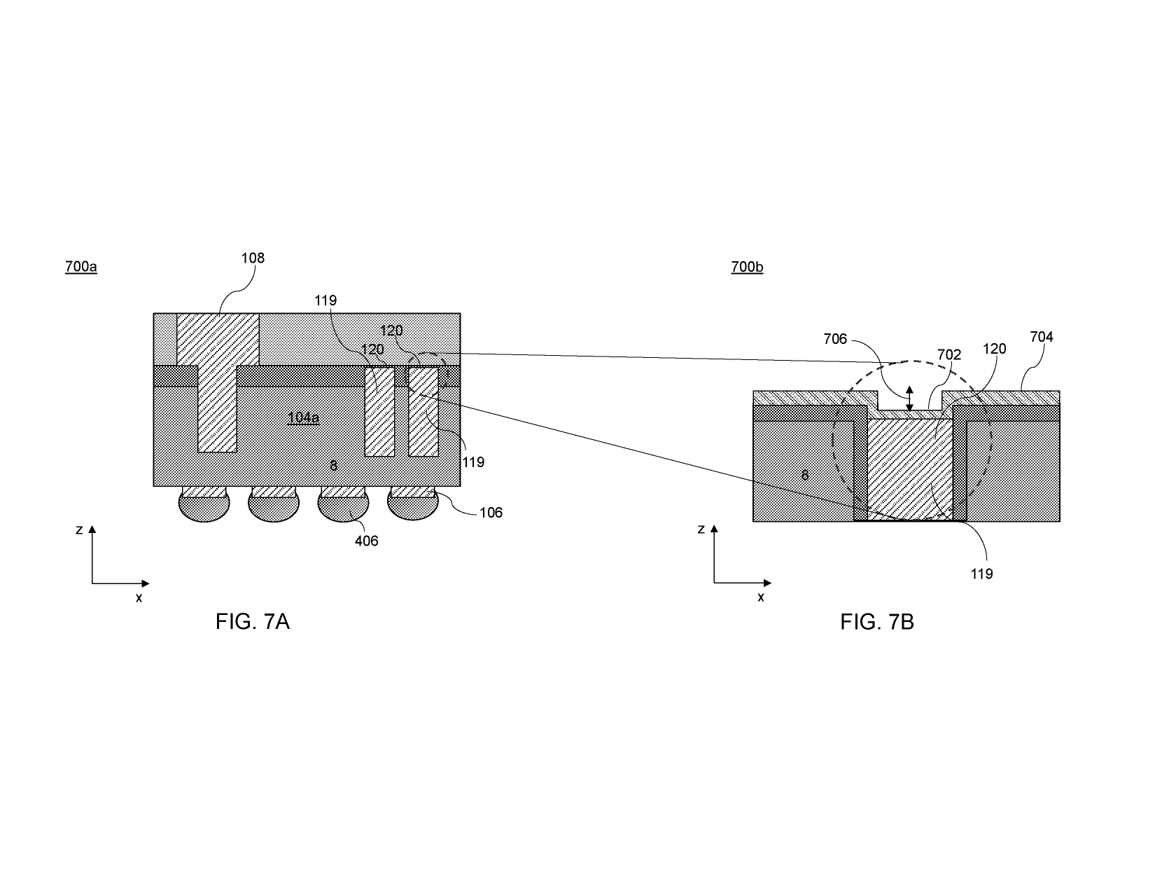

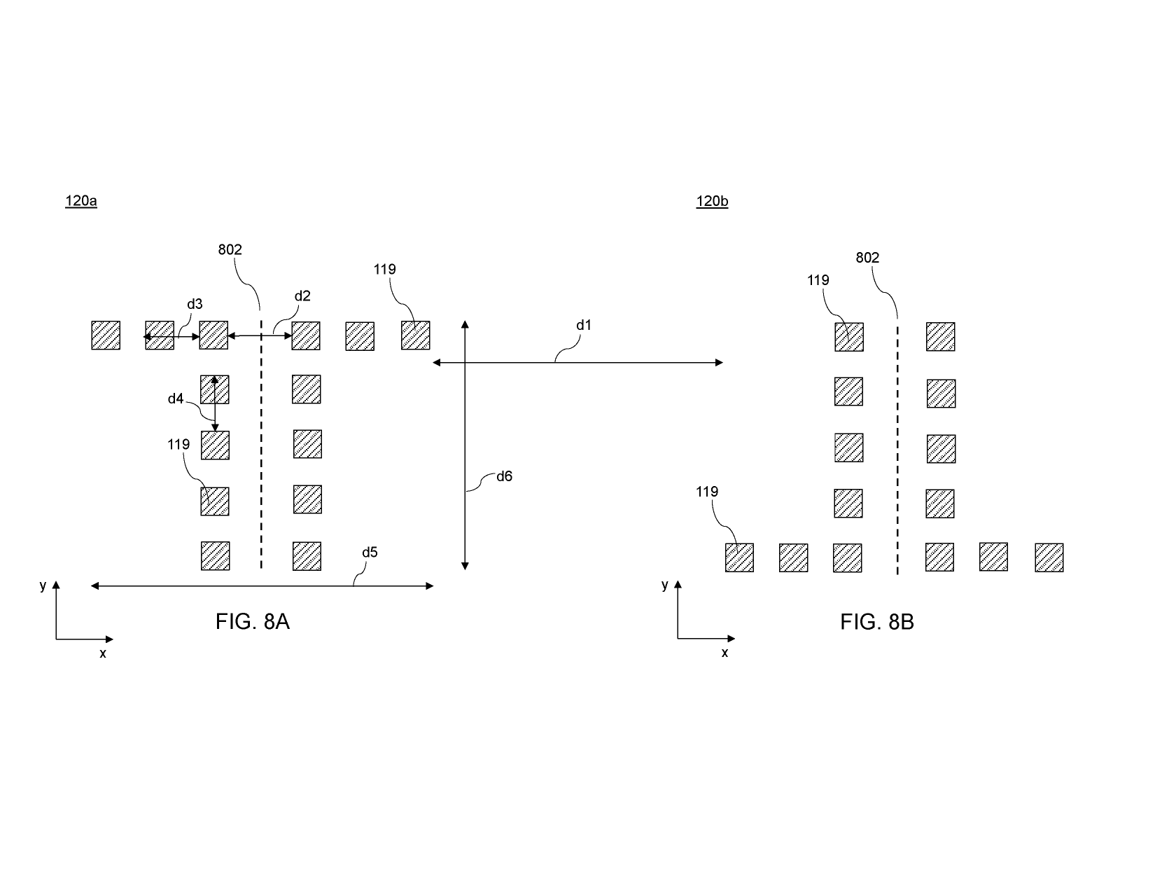

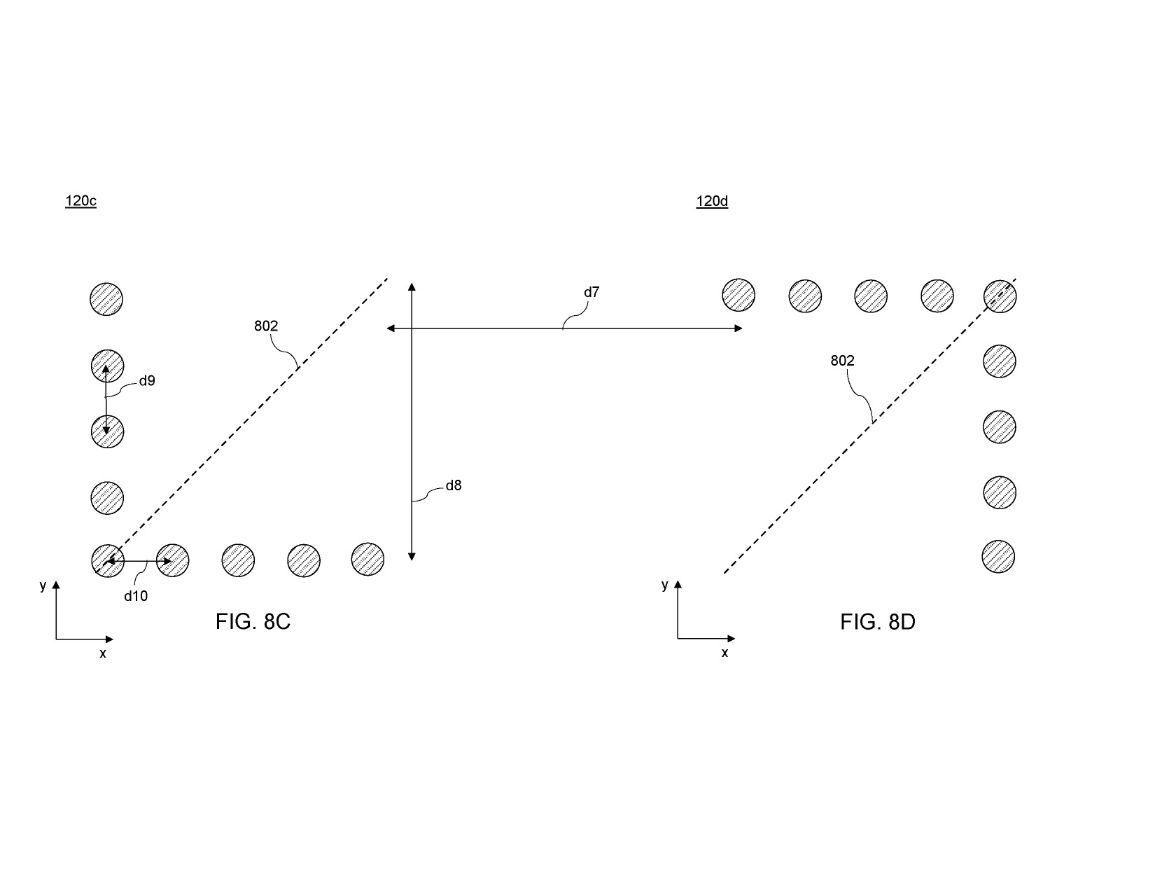

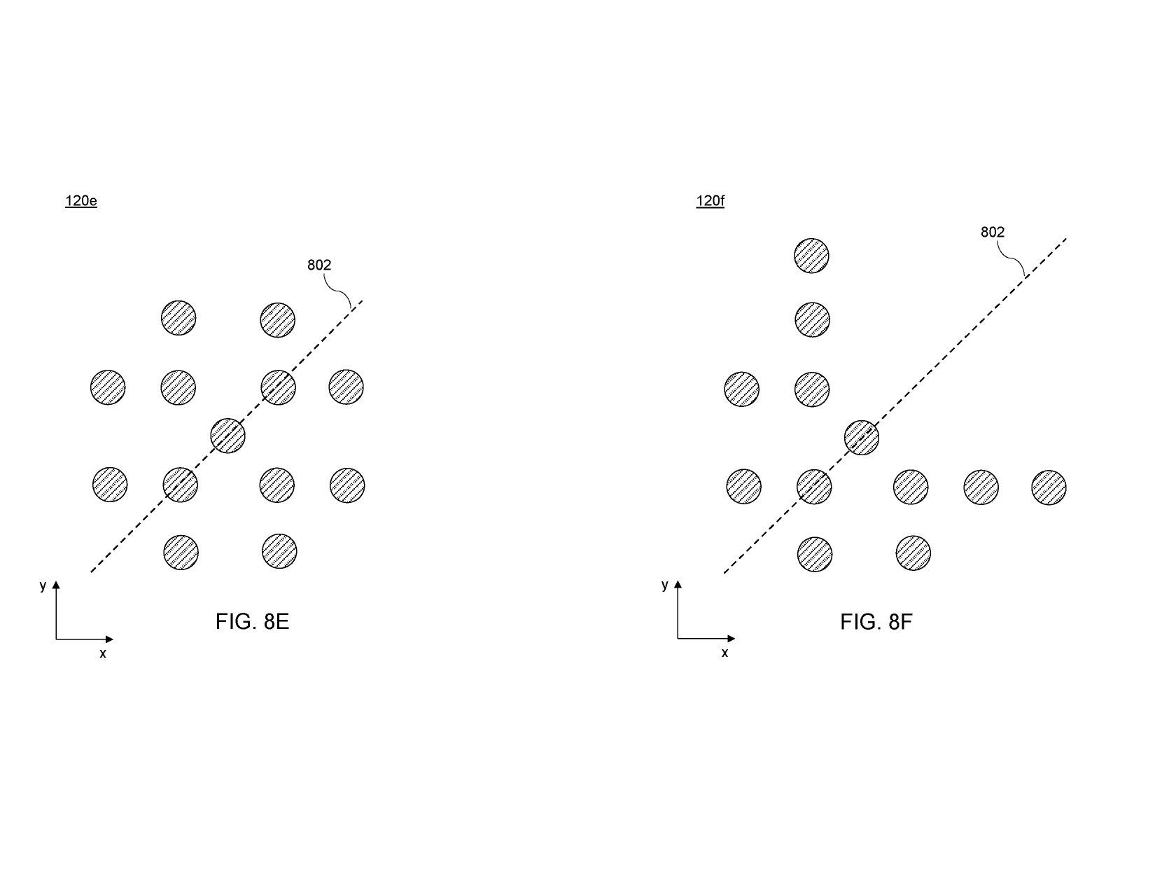

Each of the semiconductor dies (104a, 104b, 105a, 105b, 105c) may be attached to the respective first redistribution layer 102a and the second redistribution layer 102b using a pick-and-place process, as described in greater detail with reference to FIGS. 4C and 4D, below. As such, some or all of the semiconductor dies (104a, 104b, 105a, 105b, 105c) may include various alignment marks 120, which may be used for precise placement of the various semiconductor dies (104a, 104b, 105a, 105b, 105c). For example, the first semiconductor die 104a and the second semiconductor die 104b may each include at least one alignment mark 120 that may be formed as a metallic structure within a semiconductor substrate 8 of each of the first semiconductor die 104a and the second semiconductor die 104b, as shown in FIG. 1. According to various embodiments, each alignment mark 120 may be formed as a copper via 119 or as a through-silicon via 119 (e.g., see FIGS. 3D and 7B). In other embodiments, each alignment mark 120 may include a grouping of a plurality of metallic structures, as described in greater detail with reference to FIGS. 8A to 8F, below. Further, each alignment mark 120 may include one or more metallic structures having a recessed surface, as described in greater detail with reference to FIGS. 7A and 7B, below.

As described above, the semiconductor package structure 100 may be formed as one of a plurality of such semiconductor package structures 100 in a wafer-level process. In this regard, the first redistribution layer 102a may be formed over a wafer 402 (e.g., a carrier substrate) as described in greater detail with reference to FIG. 4A, below. The first redistribution layer 102a may include a first plurality of repeat units that are spatially displaced from one another over the wafer 402. Each of the first plurality of repeat units 502a may include a first semiconductor die 104a and a second semiconductor die 104b electrically coupled to the first redistribution layer 102a over each of the first plurality of repeat units as shown, for example, in FIGS. 5A and 5B.

Due to errors in the pick-and-place process, however, there may be misalignment between the location of the first semiconductor die 104a and the second semiconductor die 104b relative to the locations of the first plurality of repeat units 502a. Such errors may be corrected in forming the second redistribution layer 102b using precise measurements of the locations of the first semiconductor die 104a and the second semiconductor die 104b that may be obtained by imaging locations of the alignment marks 120, as described in greater detail with reference to FIGS. 5E and 5F, below.

In this regard, the second redistribution layer 102b may be formed over, and may be electrically coupled to, the first semiconductor die 104a and the second semiconductor die 104b such that the second redistribution layer 102b includes a second plurality of repeat units 502b that are spatially displaced from one another and are spatially aligned with a respective area 504a associated with the first semiconductor die 104a and the second semiconductor die 104b (e.g., see FIGS. 5E and 5F and related description). In some embodiments, an overlay error may be less than or equal to 0.5 microns as described in greater detail below. Various processes for forming the semiconductor package structure 100 are described below with reference to FIGS. 4A to 4N.

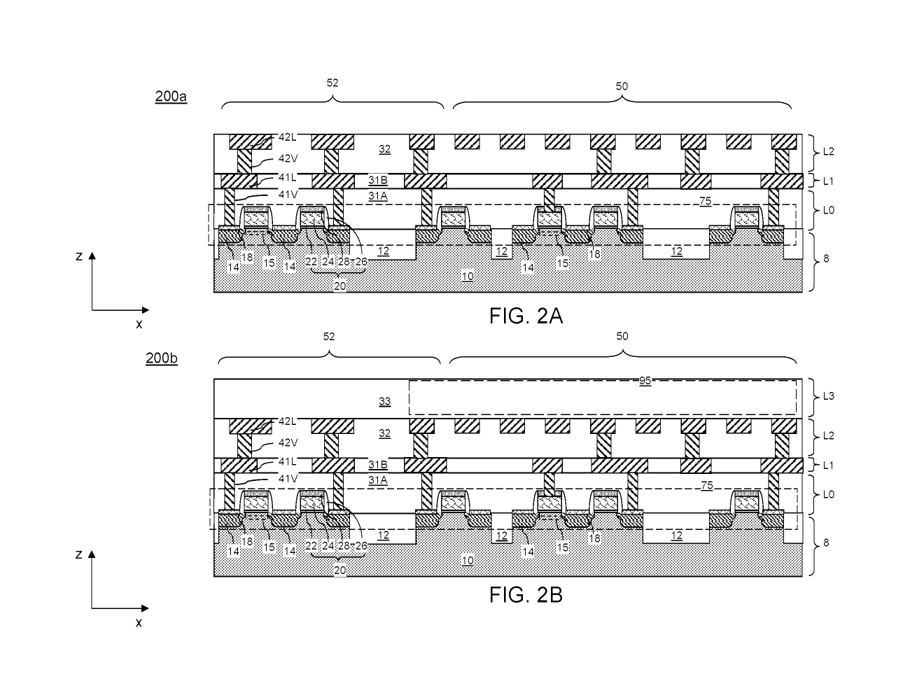

FIG. 2A is a vertical cross-sectional view of an intermediate structure 200a after formation of complementary metal-oxide-semiconductor (CMOS) transistors, metal interconnect structures, and dielectric material layers, according to various embodiments. The intermediate structure 200a may include a substrate 8, which may be a semiconductor substrate such as a commercially available silicon substrate. The substrate 8 may include a semiconductor material layer 10 at least at an upper portion thereof. The substrate 8 may include a bulk semiconductor substrate such as a silicon substrate in which the semiconductor material layer 10 continuously extends from a top surface of the substrate 8 to a bottom surface of the substrate 8, or a semiconductor-on-insulator (SOI) layer including the semiconductor material layer 10 as a top semiconductor layer overlying a buried insulator layer (such as a silicon oxide layer). The immediate structure 200a may include various device regions 50 in which devices may be subsequently formed.

The immediate structure 200a may also include a peripheral logic region 52 in which electrical connections between various devices and various peripheral circuits including field effect transistors may be subsequently formed. Semiconductor devices such as field effect transistors (FETs) may be formed on, and/or in, the semiconductor material layer 10 during a FEOL operation. For example, shallow trench isolation structures 12 may be formed in an upper portion of the semiconductor material layer 10 by forming shallow trenches and subsequently filling the shallow trenches with a dielectric material such as silicon oxide. Other suitable dielectric materials are within the contemplated scope of disclosure. Various doped wells (not expressly shown) may be formed in various regions of the upper portion of the semiconductor material layer 10 by performing masked ion implantation processes.

Gate structures 20 may be formed over the top surface of the substrate 8 by depositing and patterning a gate dielectric layer, a gate electrode layer, and a gate cap dielectric layer. Each gate structure 20 may include a vertical stack of a gate dielectric 22, a gate electrode 24, and a gate cap dielectric 28, which is herein referred to as a gate stack (22, 24, 28). Ion implantation processes may be performed to form extension implant regions, which may include source extension regions and drain extension regions. Dielectric gate spacers 26 may be formed around the gate stacks (22, 24, 28). Each assembly of a gate stack (22, 24, 28) and a dielectric gate spacer 26 may constitute a gate structure 20. Additional ion implantation processes may be performed that use the gate structures 20 as self-aligned implantation masks to form deep active regions.

Such deep active regions may include deep source regions and deep drain regions. Upper portions of the deep active regions may overlap with portions of the extension implantation regions. Each combination of an extension implantation region and a deep active region may constitute a source/drain region 14 depending on electrical biasing. A semiconductor channel 15 may be formed underneath each gate stack (22, 24, 28) between a neighboring pair of source/drain regions 14. Metal-semiconductor alloy regions 18 may be formed on the top surface of each source/drain region 14.

Field effect transistors may be formed on the semiconductor material layer 10. Each field effect transistor may include a gate structure 20, a semiconductor channel 15, a pair of source/drain regions 14 (one of which functions as a source region and another of which functions as a drain region), and optional metal-semiconductor alloy regions 18. CMOS circuits 75 may be provided on the semiconductor material layer 10, which may include a periphery circuit for the array(s) of transistors, such as thin film transistors (TFTs), and phase-change material (PCM) switches etc.

In one embodiment, the substrate 8 may include a single crystalline silicon substrate, and the CMOS circuits 75 may include a respective portion of the single crystalline silicon substrate as a semiconducting channel. As used herein, a “semiconducting” element refers to an element having electrical conductivity in the range from 1.0 x 10-6 S/cm to 1.0 x 105 S/cm. As used herein, a “semiconductor material” refers to a material having electrical conductivity in the range from 1.0 x 10-6 S/cm to 1.0 x 105 S/cm in the absence of electrical dopants therein and is capable of producing a doped material having electrical conductivity in a range from 1.0 S/cm to 1.0 x 105 S/cm upon suitable doping with an electrical dopant.

Various interconnect-level structures may be subsequently formed, which may form the front-side interconnect layer, described above. The interconnect-level structures may be referred to as lower interconnect-level structures (L0, L1, L2) and may be formed before any additional BEOL devices, such as additional memory devices. In some embodiments, one or more additional devices may be formed over one or more levels of interconnect-level metal lines. For example, the one or more additional devices may include TFTs, memory devices, or PCM switches.

The lower interconnect-level structures (L0, L1, L2) may include a contact-level structure L0, a first interconnect-level structure L1, and a second interconnect-level structure L2. The contact-level structure L0 may include a planarization dielectric layer 31A including a planarizable dielectric material such as silicon oxide and various contact via structures 41V contacting a respective one of the source/drain regions 14 or the gate electrodes 24 and formed within the planarization dielectric layer 31A.

The first interconnect-level structure L1 may include a first interconnect level dielectric (ILD) layer 31B and first metal lines 41L formed within the first ILD layer 31B. The first ILD layer 31B is also referred to as a first line-level dielectric layer. The first metal lines 41L may contact a respective one of the contact via structures 41V. The second interconnect-level structure L2 may include a second ILD layer 32 and a stack of a first via-level dielectric material layer and a second line-level dielectric material layer or a line-and-via-level dielectric material layer. The second ILD layer 32 may include second interconnect-level metal interconnect structures (42V, 42L) therewithin, which includes first metal via structures 42V and second metal lines 42L. Top surfaces of the second metal lines 42L may be coplanar with the top surface of the second ILD layer 32.

FIG. 2B is a vertical cross-sectional view of a further intermediate structure 200b structure during formation of one or more additional BEOL devices (e.g., phase-change material switch, a memory device, etc.), according to various embodiments. The one or more additional BEOL devices may be formed in the device region 50 over the second interconnect-level structure L2. A third ILD layer 33 may be formed during formation of one or more additional BEOL devices 95. The set of all structures formed at the level of the one or more BEOL devices 95 may be referred to as a third interconnect-level structure L3. Various additional interconnect layers may be formed over the intermediate structure 200b as needed, based on circuit design considerations, in other embodiments.

FIGS. 3A to 3D are vertical cross-sectional views of intermediate structures (300a, 300b, 300c, 300d) that may be used in the formation of semiconductor dies (104a, 104b), according to various embodiments. The intermediate structure 300a may include a semiconductor material layer 10 having a plurality of transistor structures 301 formed on a semiconductor substrate 8 in an FEOL process, as described above with reference to FIGS. 2A and 2B. In this example embodiment, the transistor structures 301 are illustrated as FinFET transistors, however, other types of transistor structures may be formed in the semiconductor material layer 10. For example, in other embodiments, the semiconductor material layer 10 may include CMOS circuits 75, as described above with reference to FIGS. 2A and 2B.

The semiconductor material layer 10 may include a doped semiconductor material layer 11, from which various fin structures 13 may be formed. The doped semiconductor material layer 11 may be formed by introducing n-type or p-type dopant atoms into the semiconductor substrate 8 by diffusion, ion implantation, plasma doping, etc. The resulting doped semiconductor material layer 11 may then be patterned and etched to form the fin structures 13. The fin structures 13 formed in this way may have an electrical conductivity corresponding to that of the doped semiconductor material layer 11. As such, a channel region (not shown) of each fin structure 13 may have a corresponding conductivity. In this regard, if the doped semiconductor material layer 11 contains n-type dopants, N-channel FinFET structures 301 may be subsequently formed, and if the doped semiconductor material layer 11 contains p-type dopants, P-channel FinFET structures 301 may be subsequently formed. In other embodiments, the doped semiconductor material layer 11 may be omitted and the resulting fin structures 13 may be nominally undoped.

The fin structures 13 may be further doped to form respective source and drain regions (not shown), for example, by ion implantation. In this regard, respective ends of the fin structures 13 extending into and out of the plane of the figure may be doped prior to, or subsequently after, formation of the fin structures 13 to form the source and drain regions. A dielectric material, such as silicon oxide, may then be deposited over the resulting structure to form shallow trench isolation structures 12 that may separate the various fin structures 13. Other suitable dielectric materials are within the contemplated scope of disclosure.

A plurality of gate structures 20 may then be formed over the plurality of fin structures 13. As described above, the gate structures 20 may be formed by depositing and patterning a gate dielectric layer, a gate electrode layer, and a gate cap dielectric layer. A channel region (not shown) of each fin structure 13, formed under each gate structure 20, may be further doped to fine-tune an electrical conductivity of the channel region to satisfy desired device characteristics. The intermediate structure 300a may further include a planarization dielectric layer 31A including a planarizable dielectric material such as silicon oxide. Other suitable dielectric materials are within the contemplated scope of disclosure.

The intermediate structure 300b of FIG. 3B may be formed from the intermediate structure 300a of FIG. 3A by removing a top portion of the planarization dielectric layer 31A above top surfaces of the transistor structures 301 and by forming via structures 118 through the semiconductor material layer 10. As shown, the via structures 118 may be formed in the shallow trench isolation structures 12 in regions between the transistor structures 301. The via structures 118 may have a width that is in a range from 10 nm to 20 nm, although narrower or wider via structures 118 may be used. As shown in FIG. 3B, the via structures 118 may be formed to penetrate through the semiconductor material layer 10 and into semiconductor substrate 8. In other embodiments, the via structures 118 may be formed in locations other than between transistor structures 301.

The intermediate structure 300c of FIG. 3C may be formed from the intermediate structure 300b of FIG. 3B by forming an additional layer of the planarization dielectric layer 31A over the via structures 118. First vias 304V may then be formed in the planarization dielectric layer 31A. Thus, as shown in FIG. 3C, a first via layer V1 and a first metal layer M1 may be formed. As indicated in FIG. 3C, the first via layer V1 may represent a top structure of the semiconductor material layer 10 and the first metal layer M1 may be a first layer in a front-side interconnect structure to be formed subsequently. In various embodiments, a one or more additional metal lines 304L and vias 304V may be formed over the first via layer V1 and the first metal layer M1. For example, in some embodiments, the resulting front-side interconnect structure may include 10 to 20 interconnect levels (not shown) formed in 10 to 20 respective front-side dielectric layers.

FIG. 3D is a vertical cross-sectional view of a further intermediate structure 300d that may be used to form semiconductor dies (104a, 104b), according to various embodiments. In this regard, the intermediate structure 300c of FIG. 3C may be inverted (e.g., see FIG. 3D) such that an additional BEOL process may be performed to form a back-side interconnect structure 108 (e.g., see FIG. 1). In this regard, a back-side portion of the substrate 8 may be removed by a planarization process, and a plurality of via cavities (not shown) may be formed in a remaining portion of the substrate 8. As shown in FIG. 3D, first back-side vias 310V may then be formed. A first back-side metallization layer 312 including first back-side metal lines 310L may then be formed. In addition, back-side floating vias 119 may be formed in the substrate 8. The back-side floating vias 119 may form a portion of alignment marks 120, as described in greater detail with reference to FIGS. 7A and 7B, below.

As shown in FIG. 3D, the back-side portion of the substrate 8 including the first back-side vias 310V along with the first back-side metallization layer 312 may form first components of a back-side interconnect structure. In some embodiments, a plurality of additional metal lines and vias may then be formed over the first back-side vias 310V along with the first back-side metallization layer 312 to thereby form additional components of the back-side interconnect structure. For example, in some embodiments, the resulting back-side interconnect structure may include 5 to 10 interconnect levels (not shown) formed in 5 to 10 respective back-side dielectric layers. The back-side electrical contacts 108 (e.g., see FIG. 1) may then be formed over the back-side interconnect structure.

FIG. 4A is a vertical cross-sectional view of an intermediate structure 400a that may be used in the formation of a semiconductor package structure 100, according to various embodiments. The intermediate structure 400a may correspond to a single repeat unit 502a in a two-dimensional array of similar structures (e.g., see FIGS. 5A and 5B) that may be formed on the wafer 402. As such, a plurality of semiconductor package structures 100 may be formed concurrently for batch production. To simplify the following description, processing operations are described with reference to formation of a single package structure 100 (e.g., see FIG. 1).

The intermediate structure 400a may include a first redistribution layer 102a (having electrical interconnect structures 401 formed in a dielectric layer 408) formed over a wafer 402 (e.g., a carrier substrate). The wafer 402 may further include an adhesive layer 404 located on a surface of the wafer 402 in between the wafer 402 and the first redistribution layer 102a. In some embodiments, the wafer 402 may include, for example, a polymer, silicon-based materials, such as glass, ceramics or silicon oxide, or other materials, such as aluminum oxide, combinations of any of these materials, etc. The wafer 402 may be configured to have a planar surface to accommodate attachment of one or more semiconductor dies such as the first semiconductor die 104a and the second semiconductor die 104b shown in FIG. 1.

The adhesive layer 404 may be placed on the wafer 402 to removably attach overlying structures (e.g., the first redistribution layer 102a) to the wafer 402. In an example embodiment, the adhesive layer 404 may include an ultra-violet glue, which may be configured to lose its adhesive properties when exposed to ultraviolet light. In further embodiments, other types of adhesives, such as pressure sensitive adhesives, radiation curable adhesives, light to heat conversion release coating (LTHC), epoxies, combinations of these, etc., may also be used. The adhesive layer 404 may be placed onto the wafer 402 in a semi-liquid or gel form, which may be readily deformable under pressure. In some embodiments, a semiconductor package structure 100 may be formed on the adhesive layer 404. In some embodiments, the first redistribution layer 102a may be configured as an integrated fan-out (InFO) package, although other types of packages may be used in other embodiments. In this regard, the first redistribution layer 102a may have a fan-out configuration, as described above.

The first redistribution layer 102a may include at least one insulating layer (not shown). The insulating layer may be placed over the first redistribution layer 102a and may be utilized to provide protection to, for example, the first semiconductor die 104a and the second semiconductor die 104b once the first semiconductor die 104a and the second semiconductor die 104b have been attached. In an embodiment, the insulating layer may include polybenzoxazole (PBO), although any suitable material, such as polyimide or a polyimide derivative, may alternatively be utilized. The insulating layer may be placed using, for example, a spin-coating process to deposit a film having a thickness in a range from about 2 microns to about 15 microns, such as about 5 microns, although any suitable method and thickness may alternatively be used. In some embodiments, the first redistribution layer 102a may further include a circuit layer for electrically connecting the first semiconductor die 104a and the second semiconductor die 104b to the first redistribution layer 102a.

FIG. 4B is a vertical cross-sectional view of a further intermediate structure 400b that may be used in the formation of a semiconductor package structure 100, according to various embodiments. The intermediate structure 400b may be formed from the intermediate structure 400a by forming a plurality of through-molding-material vias 142 over the first redistribution layer 102a. The through-molding-material vias 142 may be configured to surround at least one device area where the first semiconductor die 104a and the second semiconductor die 104b may be subsequently attached. The through-molding-material vias 142 may be formed on, and electrically connected to, the first redistribution layer 102a located on the wafer 402. In other embodiments, the through-molding-material vias 142 may be pre-formed as separate structures, which may then be attached to the carrier first redistribution layer 102a.

The through-molding-material vias 142 may be formed over the first redistribution layer 102a as follows. A seed layer (not shown) may be formed over the first redistribution layer 102a. The seed layer may be a thin layer of a conductive material that aids in the formation of a thicker layer during subsequent processing steps. For example, the seed layer may include a layer of titanium having a layer of copper formed thereon. The titanium may have a thickness of approximately 100 nm and the copper may have a thickness of approximately 500 nm. The seed layer may be deposited using various processes such as sputtering, evaporation, or plasma-enhanced chemical vapor deposition (PECVD), etc., depending upon the materials chosen for the seed layer.

A photoresist (not shown) may then be formed over the seed layer using, for example, a spin coating technique. The photoresist may then be patterned by exposing the photoresist to a patterned energy source (e.g., a patterned light source), thereby inducing a physical change in those portions of the photoresist exposed to the patterned light source. A developer may then be applied to the exposed photoresist to selectively remove either the exposed portion of the photoresist or the unexposed portion of the photoresist, depending upon the desired pattern. The pattern formed into the photoresist may then be used to generate the through-molding-material vias 142. The through-molding-material vias 142 may be formed in locations around an area in which the first semiconductor die 104a and the second semiconductor die 104b may be subsequently attached.

The through-molding-material vias 142 may then be formed by deposition of a conducting material in regions that are not masked by photoresist. Conductive materials that may be used to form the through-molding-material vias 142 may include copper, tungsten, or other conductive metals. Such materials may be deposited, for example, by electroplating, electroless plating, etc. In an example embodiment, an electroplating process may be used for plating the exposed conductive areas of the seed layer within openings of the photoresist. Once the through-molding-material vias 142 are formed using the photoresist and the seed layer, the photoresist may be removed using a suitable removal process. For example, a plasma ashing process may be used to remove the photoresist, whereby the temperature of the photoresist may be increased until the photoresist experiences a thermal decomposition that allows the photoresist to be removed. In other embodiments, other suitable process, such as a wet strip, may be utilized. The removal of the photoresist may expose the underlying portions of the seed layer.

Exposed portions of the seed layer (e.g., those portions that are not covered by the through-molding-material vias 142) may be removed, for example, by a wet or dry etching process. For example, in a dry etching process reactants may be directed towards the seed layer, using the through-molding-material vias 142 as masks. Alternatively, etchants may be sprayed or otherwise put into contact with the seed layer to remove the exposed portions of the seed layer. After the exposed portion of the seed layer has been removed (e.g., etched away), a portion of the first redistribution layer 102a may be exposed between the through-molding-material vias 142, thus completing the process of forming the through-molding-material vias 142.

FIG. 4C is a vertical cross-sectional view of a further intermediate structure 400c that may be used in the formation of a semiconductor package structure 100, according to various embodiments. As shown, the first semiconductor die 104a and the second semiconductor die 104b may be positioned over the first redistribution layer 102a in preparation for attaching the first semiconductor die 104a and the second semiconductor die 104b to the first redistribution layer 102a. In this regard, first semiconductor die 104a and the second semiconductor die 104b may be formed separately and may be positioned over the first redistribution layer 102a using a pick-and-place tool. Each of the first semiconductor die 104a and the second semiconductor die 104b may include front-side electrical contacts 106 and back-side electrical contacts 108, as described above with reference to FIGS. 1 and 3A to 3D. The front-side electrical contacts 106 may be provided with solder material portions 406 that may be used to electrically couple the first semiconductor die 104a and the second semiconductor die 104b.

FIGS. 4D and 4E are vertical cross-sectional views of further intermediate structures (400d, 400e) that may be used in the formation of a semiconductor package structure 100, according to various embodiments. As shown in FIG. 4D, the first semiconductor die 104a and the second semiconductor die 104b may be attached to, and electrically coupled to, the first redistribution layer 102a. For example, a flip-chip bonding process may be performed to attach the first semiconductor die 104a and the second semiconductor die 104b to the first redistribution layer 102a.

In this regard, a pick-and-place tool may position the first semiconductor die 104a and the second semiconductor die 104b relative to the first redistribution layer 102a such that the solder material portions 406 (e.g., see FIG. 4C) that are attached to the front-side electrical contacts 106 may be brought into contact with the top-side electrical contacts 110 of the first redistribution layer 102a. A reflow operation may then be performed to melt the solder material portions 406 which may, upon cooling, solidify to form electrical and mechanical connections between the first semiconductor die 104a, the second semiconductor die 104b, and the first redistribution layer 102a. An underfill material 116 may then be formed in spaces between the semiconductor dies (104a, 104b) and a top surface of the first redistribution layer 102a, as shown in FIG. 4E.

As shown in FIGS. 4D and 4E, the first semiconductor die 104a and the second semiconductor die 104b may be placed in an area between the through-molding-material vias 142 such that the first semiconductor die 104a and the second semiconductor die 104b are effectively surrounded by the through-molding-material vias 142.

In some embodiments, one or both of the first semiconductor die 104a and the second semiconductor die 104b may be a logic device die including logic circuits formed therein. In other embodiments, one or both of the first semiconductor die 104a and the second semiconductor die 104b may be configured for mobile applications and may include a power management integrated circuit (PMIC) die and a transceiver (TRX) die. One or more additional semiconductor dies (not shown) may be placed over the first redistribution layer 102a adjacent to one another in other embodiments. The first semiconductor die 104a and the second semiconductor die 104b may include a plurality of integrated circuits formed on a device substrate 8, as described above.

The device substrate 8 on which the integrated circuits of the first semiconductor die 104a and the second semiconductor die 104b are formed may include bulk silicon, doped or undoped silicon, an active layer of a silicon-on-insulator (SOI) substrate, or another doped or undoped semiconductor substrate. An SOI substrate, for example, may include a layer of a semiconductor material such as silicon, germanium, silicon germanium, SOI, silicon germanium on insulator (SGOI), or combinations thereof. Other substrates that may be used may include multi-layered substrates, gradient substrates, or hybrid orientation substrates. The integrated circuits may include a variety of active devices and passive devices such as capacitors, resistors, inductors, etc., that may be used to generate desired structural and functional requirements of the design for the first semiconductor die 104a and the second semiconductor die 104b. The integrated circuits may be formed using any suitable methods either within or on the substrate.

In some embodiments, the top ends of the through-molding-material vias 142 may be level with the top surfaces of the back-side electrical contacts 108. In other embodiments, the top ends of the through-molding-material vias 142 may be higher than the top surfaces of the back-side electrical contacts 108. Alternatively, the top ends of the through-molding-material vias 142 may be lower than the top surfaces of the back-side electrical contacts 108 but higher than the bottom surfaces of the back-side electrical contacts 108.

FIG. 4F is a vertical cross-sectional view of a further intermediate structure 400f that may be used in the formation of a semiconductor package structure 100, according to various embodiments. The intermediate structure 400f may be formed from the intermediate structure 400e of FIG. 4E by forming a first molding material 140a over the first semiconductor die 104a, the second semiconductor die 104b, the through-molding-material vias 142, and the first redistribution layer 102a. In this regard, the first molding material 140a may encapsulate the first semiconductor die 104a, the second semiconductor die 104b, and the through-molding-material vias 142. In some embodiments, the first molding material 140a may fill gaps between the first semiconductor die 104a and the second semiconductor die 104b and may mechanically strengthen the intermediate structure 400f.

The first molding material 140a may include a molding compound resin such as polyimide, PPS, PEEK, PES, a heat resistant crystal resin, combinations of these, etc. The encapsulation of the first semiconductor die 104a, the second semiconductor die 104b, and the through-molding-material vias 142 may be performed in a molding device (not shown in FIG. 4F). The first molding material 140a may be placed within a molding cavity of the molding device, or else may be injected into the molding cavity through an injection port. Once the first molding material 140a has been placed into the molding cavity such that the first molding material 140a may encapsulate the wafer 402, the first semiconductor die 104a, the second semiconductor die 104b, and the through-molding-material vias 142, the first molding material 140a may then be cured to harden the first molding material 140a. Additionally, initiators and/or catalysts may be included within the first molding material 140a to better control the curing process. In some embodiments, a top surface of the first molding material 140a may be higher than the top ends of the through-molding-material vias 142 and the top surface of the first semiconductor die 104a and the second semiconductor die 104b, as shown in FIG. 4F.

FIG. 4G is a vertical cross-sectional view of a further intermediate structure 400g that may be used in the formation of a semiconductor package structure 100, according to various embodiments. The intermediate structure 400g may be formed from the intermediate structure 400f of FIG. 4F by performing a thinning process to remove a top portion of the first molding material 140a. The thinning process may be performed on the first molding material 140a to reveal the top ends of the through-molding-material vias 142 and the top surfaces of the back-side electrical contacts 108, as shown in FIG. 4G.

The thinning process may include a mechanical grinding or chemical mechanical planarization (CMP) process whereby chemical etchants and abrasives are utilized to react and grind away a portion of the first molding material 140a to expose top surfaces of the through-molding-material vias 142 and the back-side electrical contacts 108. The resulting structure is shown in FIG. 4G. The thinning process may also remove top portions of the through-molding-material vias 142 and/or top portions of the back-side electrical contacts 108 such that the top ends of the through-molding-material vias 142, top surfaces of the back-side electrical contacts 108, and a top surface of the first molding material 140a are level with one another, as shown in FIG. 4G. Although the above-described CMP process may be used to perform the thinning process, various other removal processes may be used in other embodiments. For example, one or more chemical etching processes may be performed to thin the first molding material 140a, the first semiconductor die 104a and the second semiconductor die 104b, and the through-molding-material vias 142. All such alternative thinning processes are within the contemplated scope of this disclosure.

The structure of FIG. 4G, including the first semiconductor die 104a, the second semiconductor die 104b, the through-molding-material vias 142, and the first molding material 140a may be referred to as an encapsulated semiconductor device 400g. Further, the encapsulated semiconductor device 400g may be formed as one of a plurality of similar encapsulated semiconductor devices 400g on a wafer 402 (e.g., see FIGS. 5A and 5B). Accordingly, in each encapsulated semiconductor device 400g, the first semiconductor die 104a and the second semiconductor die 104b may be disposed in a die area, the through-molding-material vias 142 may extend through the encapsulated semiconductor device 400g outside of the die area, and the first molding material 140a may encapsulate the first semiconductor die 104a, the second semiconductor die 104b, and the through-molding-material vias 142.

FIG. 4H is a vertical cross-sectional view of a further intermediate structure 400h that may be used in the formation of a semiconductor package structure 100, according to various embodiments. The intermediate structure 400h may be formed from the intermediate structure 400g of FIG. 4G by forming the second redistribution layer 102b over a top side of the intermediate structure 400g (i.e., the encapsulated semiconductor device 400g). The second redistribution layer 102b may be electrically connected to the first semiconductor die 104a and the second semiconductor die 104b and the through-molding-material vias 142. In some embodiments, the second redistribution layer 102b may be formed over the encapsulated semiconductor device 400g (including the first molding material 140a, the first semiconductor die 104a, and the second semiconductor die 104b) to connect to the back-side electrical contacts 108 of the first semiconductor die 104a, the second semiconductor die 104b, and the through-molding-material vias 142 to the second redistribution layer 102b.

The second redistribution layer 102b may be formed by depositing a dielectric material layer 408 and patterning the dielectric material layer 408 to form a patterned dielectric layer 408. A conductive material may then be formed over the patterned dielectric layer 408, for example, by electroplating. The process may then be repeated several times to form the second redistribution layer 102b that may include a plurality of electrical interconnect structures 401 formed within the dielectric material layer 408. The material of the electrical interconnect structures 401 may include a metal or a metal alloy including aluminum, copper, tungsten, and/or alloys thereof. The dielectric material layers 408 may be formed of dielectric materials such as polymers, oxides, nitrides, carbides, carbon nitrides, combinations thereof, and/or multi-layers thereof. The electrical interconnect structures 401 may be formed in the dielectric material layers 408 and may be electrically connected to the first semiconductor die 104a and the second semiconductor die 104b and the through-molding-material vias 142. In some embodiments, the electrical interconnect structures 401 may further include an under-bump metallurgy (UBM) layer (not shown) formed as part of the top-side electrical connections 110. As shown in FIG. 4H, the second redistribution layer 102b and the first redistribution layer 102a may be disposed on opposite sides of the encapsulated semiconductor device 400g. According to some embodiments, at least one of the first redistribution layer 102a and the second redistribution layer 102b include features having at least one of a sub-micron line width or a sub-micron line spacing.

FIGS. 4I to 4L are vertical cross-sectional views of further intermediate structures (400i to 400l) that may be used in the formation of a semiconductor package structure 100, according to various embodiments. The intermediate structure 400i may be formed from the intermediate structure 400h of FIG. 4H by attaching additional semiconductor dies (105a, 105b, 105c) to the second redistribution layer 102b. The additional semiconductor dies (105a, 105b, 105c) may be attached to the second redistribution layer 102b by performing processes similar to those used to attach the first semiconductor die 104a and the second semiconductor die 104b to the first redistribution layer 102a, as described in greater detail with reference to FIGS. 4C and 4D, above.

In this regard, a flip-chip process may be performed in which a pick-and-place tool may position the additional semiconductor dies (105a, 105b, 105c) over the second redistribution layer 102b. A reflow operation may then be performed to attach the additional semiconductor dies (105a, 105b, 105c) electrically and mechanically to the second redistribution layer. In further processing operations, an underfill material 116 may then be formed in spaces between the additional semiconductor dies (105a, 105b, 105c) and a top surface of the second redistribution layer 102b, as shown in FIG. 4J. A second molding material 140b may then be formed over and around the additional semiconductor dies (105a, 105b, 105c) as shown in FIGS. 4K and 4L using techniques described above with reference to FIGS. 4F and 4G.

FIGS. 4M and 4N are vertical cross-sectional views of further intermediate structures (400m, 400n) that may be used in the formation of a semiconductor package structure 100, according to various embodiments. The intermediate structure 400n may be formed from the intermediate structure 400l of FIG. 4L by attaching a second wafer 402b (i.e., carrier substrate) to the intermediate structure 400l using an adhesive 404 and by removing the first wafer 402a. As described above, the first wafer 402a may be removed by de-activating the adhesive 404 by application of heat or ultraviolet radiation. Removal of the first wafer 402a may expose a surface of the first redistribution layer 102a. The intermediate structure 400n of FIG. 4N may then be formed from the intermediate structure 400m of FIG. 4M by forming bottom-side electrical contacts 112 on the first redistribution layer 102a. Solder material portions 406 may then be formed over the bottom-side electrical contacts 112. The semiconductor package structure 100 of FIG. 1 may then be formed by removing the second wafer 402b from the intermediate structure 400n.

FIG. 5A is a top view of a wafer-level structure 500a that may be used in the formation of a plurality of semiconductor package structures 100, according to various embodiments. As shown in FIG. 5A, the wafer-level structure 500a may include a first redistribution layer 102a formed over a wafer 402a. The first redistribution layer 102a may include a first plurality of repeat units 502a that are spatially displaced from one another. In this regard, the first redistribution layer 102a may be arranged as a periodic array of the first plurality of repeat units 502a. As shown in FIG. 5A, each of the first plurality of repeat units 502a may have a rectangular shape and may have a uniform angular orientation.

As described above, one or more semiconductor dies (104a, 104b) may then be coupled to the first redistribution layer 102a over each of the first plurality of repeat units 502a. As such, each of the plurality of repeat units 502a may correspond to a respective semiconductor package structure 100 to be subsequently formed. In this regard, the one or more semiconductor dies (104a, 104b) formed over each of the plurality of repeat units 502a may correspond to a first area (504a1, 504a2) that may be associated with the one or more semiconductor dies (104a, 104b). In the absence of pick-and-place errors, each first area (504a1, 504a2) associated with the one or more semiconductor dies (104a, 104b) may be spatially aligned with each of the first plurality of repeat units 502a of the first redistribution layer 102a. In practice, however, pick-and-place errors may be difficult to avoid with ever decreasing feature sizes. As such, each first area 504a may have a slight misalignment relative to respective ones of the first plurality of repeat units 502a. According to various embodiments, such pick-and-place errors may be measured and the measured pick-and-place errors may be used to make corrections to the placement of various features of the second redistribution layer 102b to be formed subsequently.

FIG. 5B is a top view of a further wafer-level structure 500b that may be used in the formation of a plurality of semiconductor package structures, according to various embodiments. The wafer-level structure 500b of FIG. 5B may be formed from the wafer-level structure 500a of FIG. 5A by coupling one or more semiconductor dies (104a, 104b) to the first redistribution layer 102a over each of the remaining first plurality of repeat units 502a in FIG. 5A. As described above, the placement of the one or more semiconductor dies (104a, 104b) may include pick-and-place errors. As such, there may be some degree of misalignment between each first area (504a1, 504a2), associated with the one or more semiconductor dies (104a, 104b), and a respective one of the first plurality of repeat units 502a. An exposure tool that may be used to generate the second redistribution layer 102b may measure a degree of misalignment between each first area (504a1, 504a2) and each respective repeat unit 502a and may make corrections to spatial features associated with the second redistribution layer 102b to be subsequently formed. The measurements may be made by capturing images of various alignment marks 120 formed on each of the one or more semiconductor dies (104a, 104b), as described in greater detail with reference to FIGS. 5D and 6A to 8F, below.

Corrections to the placement of features of the second redistribution layer 102b may include coarse adjustments and fine adjustments. FIG. 5B illustrates an example of a coarse adjustment in which an overall pattern for placement of the second redistribution layer 102b may be rotated relative to a pattern associated with the first redistribution layer 102a. The rotation illustrated in FIG. 5B may be exaggerated for the purpose of illustration. In practice, the overall rotation of the first redistribution layer 102a relative to the second redistribution layer 102b may be a small fraction of a degree. The coarse error correction may be determined by measuring positions of two or more first areas (504a1, 504a2). In addition to the coarse alignment adjustment illustrated in FIG. 5B relative to FIG. 5A, fine adjustments may be made as described in greater detail with reference to FIGS. 5C to 5F, below.

FIG. 5C is a top view of a further wafer-level structure 500c illustrating placement errors, and FIG. 5D is an expanded top view of a portion of the wafer-level structure 500c of FIG. 5C, according to various embodiments. As shown in FIGS. 5C and 5D the various first areas (504a1, 504a2) may have placement errors that may include rotations from one of the first areas 504a1 to another of the first areas 504a2. To accurately measure placement errors, each of the one or more semiconductor dies (104a, 104b) may include at least one alignment mark 120. Each alignment mark 120 may include fine features such that imaging the various alignment marks 120 may allow the exposure tool to accurately determine fine corrections to the placement of features of the second redistribution layer 102b, as described in greater detail with reference to FIGS. 7A to 8F, below.

FIG. 5E is a top view of a further wafer-level structure 500e that may be used in the formation of a plurality of semiconductor package structures 100, and FIG. 5F is an expanded top view of a portion of the wafer-level structure 500e of FIG. 5E, according to various embodiments. As shown in FIGS. 5E and 5F, the wafer-level structure 500e may include a second redistribution layer 102b formed over, and electrically coupled to, the one or more semiconductor dies (104a, 104b). As shown in FIG. 5E, the second redistribution layer 102b may include a second plurality of repeat units 502b that are spatially displaced from one another. Each of the second plurality of repeat units 502b may have a respective second area (504b1, 504b2) that may be spatially aligned with a respective first area (504a1, 504a2) associated with one or more semiconductor dies (104a, 104b). For example, in some embodiments, the second area (504b1, 504b2) may be aligned with the respective first area (504a1, 504a2) such that an overlay error is less than or equal to 0.5 microns. As described above, once the second redistribution layer 102b has been formed (including coarse and fine placement corrections), one or more additional semiconductor dies (105a, 105b, 105c) may be attached to the second redistribution layer 102b.

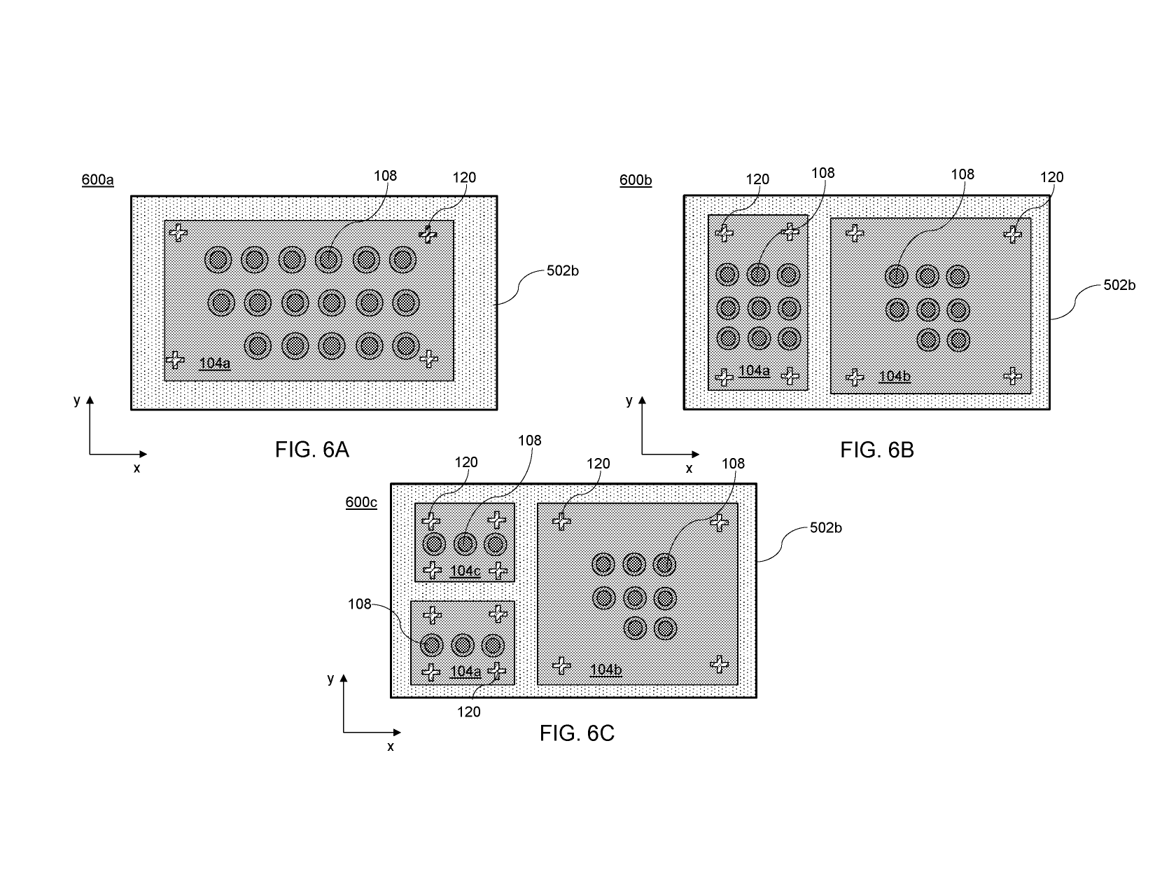

FIGS. 6A to 6C illustrate top views of respective configurations (600a, 600b, 600c) in which various semiconductor dies each include back-side electrical contacts 108 and alignment marks 120, according to various embodiments. In the first configuration 600a, a single semiconductor die 104a may be attached to the second redistribution layer 102b within each of the second plurality of repeat units 502b. Similarly, in the second configuration 600b, a first semiconductor die 104a and a second semiconductor die 104b may be attached to the second redistribution layer 102b within each of the second plurality of repeat units 502b. In the third configuration 600c, a first semiconductor die 104a, a second semiconductor die 104b, and a third semiconductor die 104c may be attached to the second redistribution layer 102b within each of the second plurality of repeat units 502b. As shown, each of the various semiconductor dies (104a, 104b, 104c) may include back-side electrical contacts 108 and two or more alignment marks 120. The use of two or more alignment marks 120 on each of the semiconductor dies (104a, 104b, 104c) in the various configurations (600a, 600b, 600c) may allow determination of precise position and alignment data for each of the second plurality of repeat units 502b.

FIG. 7A is a vertical cross-sectional view of a semiconductor die 104a that includes back-side electrical contacts 108 and alignment marks 120, and FIG. 7B is a vertical cross-sectional view of a portion of the semiconductor die 104a of FIG. 7A showing details of an alignment mark 120, according to various embodiments. According to various embodiment, each alignment mark 120 may be a metallic via structure 119 formed within a semiconductor substrate 8 of the semiconductor die 104a. For example, each alignment mark 120 may be formed as a copper via 119 or a through-silicon via 119. The alignment mark 120 may be formed using processes similar to those described above with reference to FIG. 3B in the context of forming conductive via structures 119. Unlike the via structures 118 of FIG. 3D, however, the alignment marks 120 may be connected to via structures 119 that are configured to be electrically floating (i.e., not electrically connected to conducting interconnect structures 401). Further, to improve visibility of the alignment marks 120, each alignment mark 120 may include an alignment mark surface 702 that is recessed from an interface 704 by a recess distance 706 that is between 30 microns and 40 microns, as shown in FIG. 7B.

FIGS. 8A to 8F are top views of example alignment marks (120a, 120b, 120c, 120d, 120e, 120f) that each include a plurality via structures 119, according to various embodiments. As shown, each of the alignment marks (120a, 120b, 120c, 120d, 120e, 120f) may include a plurality of via structures 119 formed in a given spatial arrangement having a mirror symmetry plane 802. Alternatively, various other embodiments may include alignment marks that have a non-symmetrical arrangement of via structures 119 (not shown). In various embodiments, the example alignment marks (120a, 120b, 120c, 120d, 120e, 120f) may be used separately on respective semiconductor dies (104a, 104b, 105a, 105b, 105c).

Alternatively, various sets of alignment marks (120a, 120b, 120c, 120d, 120e, 120f) may be used together. For example, alignment marks 120a and 120b may be formed as a complementary pair of alignment marks (120a, 120b) on one or more semiconductor dies (104a, 104b, 105a, 105b, 105c). Similarly, alignment marks 120c and 120d may be used together as a complementary pair of alignment marks (120c, 120d), as may alignment marks 120e and 120f be used as a complementary pair of alignment marks (120e, 120f). Various other embodiments may include various different groupings of alignment marks (120a, 120b, 120c, 120d, 120e, 120f) including sets of three, four, etc., alignment marks (120a, 120b, 120c, 120d, 120e, 120f).

Each of the alignment marks (120a, 120b, 120c, 120d, 120e, 120f) may have relatively small spatial feature separations to allow precise determination of fine alignment adjustments described above with reference to FIGS. 5C to 5F. For example, the alignment marks (120a, 120b) of FIGS. 8A and 8B may have example feature distances given by d1 = 50 microns, d2 = 15 microns, d3 = 9 microns, d4 = 9 microns, d5 = 55.5 microns, and d6 = 40.5 microns. These values of feature distances are provided merely as examples and various other dimensions may be provided in other embodiments. In further example embodiments, the alignment marks (120c, 120d) of FIGS. 8C and 8D may have example feature distances given by d7 = 50 microns, d8 = 40.5 microns, d9 = 9 microns, and d10 = 9 microns. Again, these values of feature distances are provided merely as examples and various other dimensions may be provided in other embodiments.

The remaining embodiments including the alignment marks (120e, 120f) of FIGS. 8E and 8F may have similar example feature distances. As described above, each of the alignment marks (120a, 120b, 120c, 120d, 120e, 120f) may have a mirror symmetry plane 802. In further embodiments, alignment marks 120 may be provided that have greater or reduced symmetry. For example, the alignment mark 120e may additionally have a four-fold rotation symmetry about its midpoint. As mentioned above, other embodiment alignment marks 120 may have greater symmetry, reduced symmetry, or no particular symmetry.

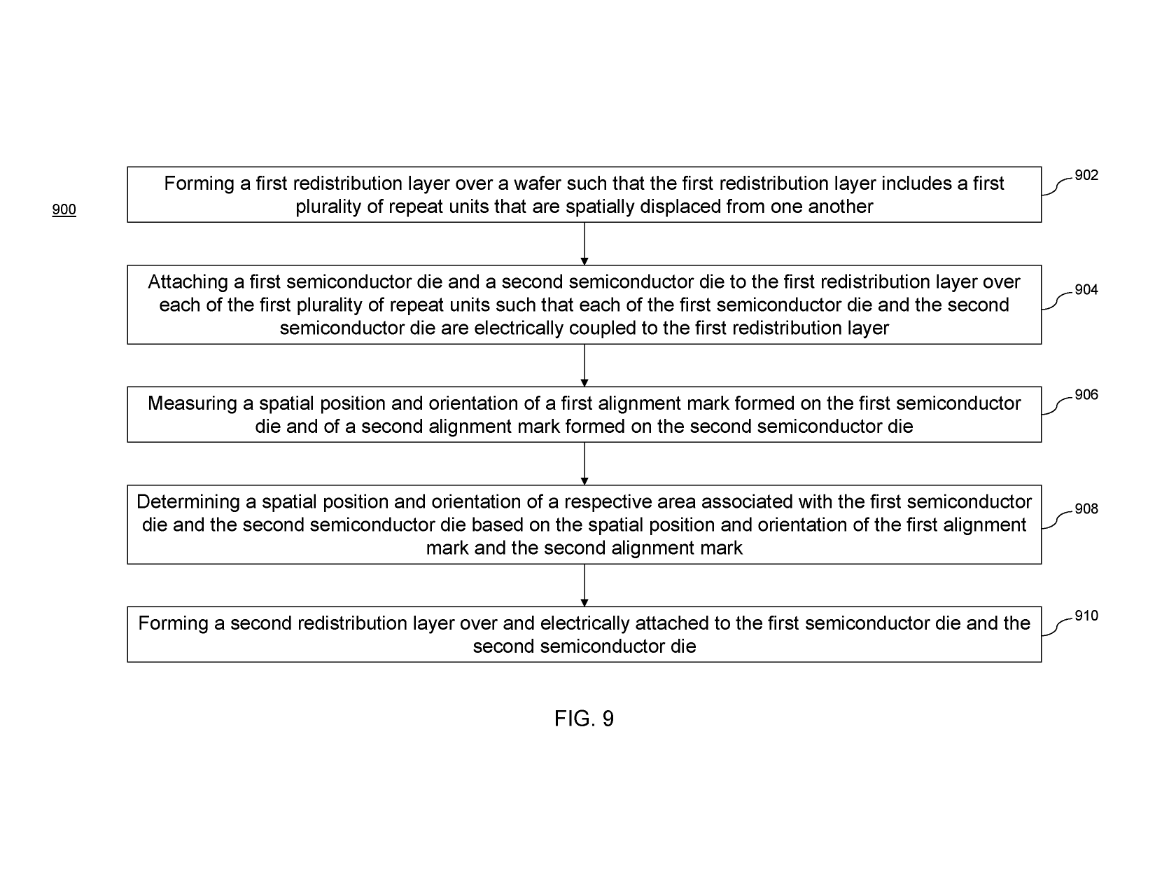

FIG. 9 is a flowchart illustrating operations of a method 900 of forming wafer-level semiconductor structure (400h, 500e), according to various embodiments. In operation 902, the method 900 may include forming a first redistribution layer 102a over a wafer 402a such that the first redistribution layer 102a includes a first plurality of repeat units 502a that are spatially displaced from one another. In operation 904, the method 900 may include attaching a first semiconductor die 104a and a second semiconductor die 104b to the first redistribution layer 102a over each of the first plurality of repeat units 502a such that each of the first semiconductor die 104a and the second semiconductor die 104b are electrically coupled to the first redistribution layer 102a. In operation 906, the method 900 may include measuring a spatial position and orientation of a first alignment mark 120 formed on the first semiconductor die 104a and of a second alignment mark 120 formed on the second semiconductor die 104b.

In operation 908, the method 900 may include determining a spatial position and orientation of a respective area 504a associated with the first semiconductor die 104a and the second semiconductor die 104b based on the spatial position and orientation of the first alignment mark 120 and the second alignment mark 120. In operation 910, the method 900 may include forming a second redistribution layer 102b over and electrically attached to the first semiconductor die 104a and the second semiconductor die 104b by performing additional operations. According to the method 900, such additional operations may include forming a second plurality of repeat units 502b that are spatially displaced from one another such each repeat unit may include redistribution layer electrical connections 110.

In a further operation, the method 900 may include spatially aligning each of the second plurality of repeat units 502b with the respective areas 504a associated with the first semiconductor die 104a and the second semiconductor die 104b based on the spatial position and orientation of the respective areas 504a associated with the first semiconductor die 104a and the second semiconductor die 104b. In a further operation, the method 900 may include electrically connecting the redistribution layer electrical connections 110 to semiconductor die electrical connections 106 formed on the first semiconductor die 104a and the second semiconductor die 104b. In spatially aligning each of the second plurality of repeat units 502b with the respective area 504a associated with the first semiconductor die 104a and the second semiconductor die 104b, the method 900 may further include controlling a spatial position and orientation the second plurality of repeat units 502b such that an overlay error is less than or equal to 0.5 microns.

The method 900 may further include forming each of the first alignment mark 120 on the first semiconductor die 104a and the second alignment mark 120 on the second semiconductor die 104b to include respective copper vias 119 or respective through-silicon vias 119 each including an alignment mark surface 702 that is recessed from an interface 704 by a recess distance 706 that is between 30 microns and 40 microns. In spatially aligning each of the second plurality of repeat units 502b with the respective area 504a associated with the first semiconductor die 104a and the second semiconductor die 104b, the method 900 may further performing a course alignment (e.g., see FIGS. 5A and 5B) and a fine alignment (e.g., see FIGS. 5C to 5F) of the repeat units 502b of the second redistribution layer 102b.

The course alignment operation may be performed to determine a position and rough orientation for each of the second plurality of repeat units 502b to be formed subsequently by determining a position and orientation of at least two respective areas (504a1, 504a2) associated with respective first semiconductor dies 104a and second semiconductor dies 104b. The fine alignment operation may be performed to determine a precise orientation for each of the second plurality of repeat units 502b to be formed subsequently based on an orientation of the first alignment mark 120 formed on the first semiconductor die 104a and of the second alignment mark 120 formed on the second semiconductor die 104b.

Referring to all drawings and according to various embodiments of the present disclosure, a semiconductor package structure 100 is provided. The semiconductor package structure 100 may include a first redistribution layer 102a and a first semiconductor die 104a attached to the first redistribution layer 102a. The first semiconductor die 104a may include first front-side electrical contacts 106 and first back-side electrical contacts 108 such that the first front-side electrical contacts 106 are electrically connected to the first redistribution layer 102a. The semiconductor package structure 100 may further include a second redistribution layer 102b formed over the first semiconductor die 104a such that the second redistribution layer 102b is electrically connected to the first back-side electrical contacts 108 of the first semiconductor die 104a. The semiconductor package structure 100 may further include a second semiconductor die 105a attached to the second redistribution layer 102b and positioned vertically over the first semiconductor die 104a. According to various embodiments, the first semiconductor die 104a further may include at least two alignment marks 120 that are separated by at least 50microns.

According to various embodiments, a first area 504a associated with the first semiconductor die 104a may be aligned with a second area 504b associated with the second redistribution layer 102b such that an overlay error is less than or equal to 0.5 microns. Further, the first area 504a may correspond to a first spatial arrangement of the first back-side electrical contacts 108 of the first semiconductor die 104a, and the second area 504b may correspond to a second spatial arrangement of corresponding redistribution layer electrical connections 110. At least one of the first redistribution layer 102a and the second redistribution layer 102b include features having at least one of a sub-micron line width or a sub-micron line spacing. The at least two alignment marks 120 may metallic via structures 119 formed within a semiconductor substrate 8 of the first semiconductor die 104a.

In some embodiments, the at least two alignment marks 120 may be formed as copper vias 119. According to various embodiments, the semiconductor substrate 8 may include silicon and the at least two alignment marks 120 may be formed as through-silicon vias 119. In further embodiments, at least two alignment marks 120 may each have an alignment mark surface 702 that is recessed from an interface 704 by a recess distance 706 that is between 30 microns and 40 microns. Further, in some embodiments, the at least two alignment marks 120 may each include a shape having a mirror symmetry plane 802. And in still further embodiments, at least one of the at least two alignment marks 120 further may include a four-fold rotational symmetry (e.g., see FIG. 8E).

According to still further embodiments, a wafer-level semiconductor structure (400h, 500e) is provided. The wafer-level semiconductor structure (400h, 500e) may include a first redistribution layer 102a formed over a wafer 402a having a first plurality of repeat units 502a that are spatially displaced from one another. The wafer-level semiconductor structure (400h, 500e) may further include a first semiconductor die 104a and a second semiconductor die 104b electrically coupled to the first redistribution layer 102a over each of the first plurality of repeat units 502a, and a second redistribution layer 102b formed over, and electrically coupled to, the first semiconductor die 104a and the second semiconductor die 104b. The second redistribution layer 102b may include a second plurality of repeat units 502b that are spatially displaced from one another, and each of the second plurality of repeat units 502b may be spatially aligned with a respective area 504a associated with the first semiconductor die 104a and the second semiconductor die 104b such that an overlay error is less than or equal to 0.5 microns.

Each of the first semiconductor die 104a and the second semiconductor die 104b may include at least one alignment mark 120. In some embodiments, the at least one alignment mark 120 may be a metallic structure 119 formed within a semiconductor substrate 8 of each of the first semiconductor die 104a and the second semiconductor die 104b. For example, the at least one alignment mark 120 may be formed as a copper via 119 or a through-silicon via 119. In various embodiments, the at least one alignment mark 120 may include an alignment mark surface 702 that is recessed from an interface 704 by a recess distance 706 that is between 30 microns and 40 microns. Further, in some embodiments, the at least one alignment mark 120 may include a shape having a mirror symmetry plane 802. In still further embodiments, the wafer-level semiconductor structure (400i to 400n) may include a third semiconductor die 105a and a fourth semiconductor die 105b electrically coupled to the second redistribution layer 102b over each of the second plurality of repeat units 502b.

The various embodiments disclosed herein may be advantageous by providing systems and methods to improve accuracy of placement of components of a semiconductor package 100. In this regard, a semiconductor package 100 may be formed by attaching semiconductor dies (104a, 104b) to a first redistribution layer 102a and forming a second redistribution layer 102b over the semiconductor dies (104a, 104b). Embodiment systems and methods may provide alignment marks (120a, 120b, 120c, 120d, 120e, 120f) having detailed features that allow precise measurement of placement errors of the semiconductor dies (104a, 104b). Such measurements may then be used to adjust features of the second redistribution layer 102b to correct for placement errors of the semiconductor dies (104a, 104b).

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. An encapsulated semiconductor device, comprising:
a first redistribution layer comprising a first plurality of repeat units;
a first semiconductor die and a second semiconductor die attached to the first redistribution layer over each of the first plurality of repeat units;
a molding material encapsulating the first semiconductor die and the second semiconductor die;
through-molding-material vias extending through the molding material to provide electrical connections between the first redistribution layer and a second redistribution layer; and
the second redistribution layer formed over the molding material and electrically connected to back-side electrical contacts of the first semiconductor die and the second semiconductor die.

2. The encapsulated semiconductor device of claim 1, wherein the through-molding-material vias surround a device area where the first semiconductor die and the second semiconductor die are located.

3. The encapsulated semiconductor device of claim 1, wherein top surfaces of the through-molding-material vias, top surfaces of the back-side electrical contacts, and a top surface of the molding material are coplanar.

4. The encapsulated semiconductor device of claim 1, wherein the molding material comprises a molding compound resin.

5. The encapsulated semiconductor device of claim 1, further comprising an underfill material formed in spaces between the first semiconductor die and the first redistribution layer.

6. The encapsulated semiconductor device of claim 1, further comprising a third semiconductor die attached to the second redistribution layer and positioned vertically over the first semiconductor die.

7. A semiconductor package structure, comprising:
a first redistribution layer;
a first semiconductor die attached to the first redistribution layer, wherein the first semiconductor die comprises front-side electrical contacts electrically connected to the first redistribution layer and back-side electrical contacts;
a molding material formed around the first semiconductor die;
a second redistribution layer formed over the molding material and the first semiconductor die, the second redistribution layer electrically connected to the back-side electrical contacts of the first semiconductor die; and
a second semiconductor die attached to the second redistribution layer and positioned vertically over the first semiconductor die.

8. The semiconductor package structure of claim 7, further comprising through-molding-material vias extending through the molding material to provide electrical connections between the first redistribution layer and the second redistribution layer.

9. The semiconductor package structure of claim 7, wherein the first semiconductor die comprises an alignment mark formed as a metallic structure within a semiconductor substrate of the first semiconductor die.

10. The semiconductor package structure of claim 9, wherein the alignment mark comprises an alignment mark surface that is recessed from an interface by a recess distance that is between 30 microns and 40 microns.

11. The semiconductor package structure of claim 7, further comprising a third semiconductor die and a fourth semiconductor die attached to the second redistribution layer.

12. The semiconductor package structure of claim 7, wherein the first semiconductor die further comprises at least two alignment marks that are separated by at least 50 microns.

13. A wafer-level semiconductor structure, comprising:
a first redistribution layer formed over a wafer, wherein the first redistribution layer comprises a first plurality of repeat units that are spatially displaced from one another;
a first semiconductor die and a second semiconductor die attached to the first redistribution layer over the first plurality of repeat units;
a molding material encapsulating the first semiconductor die and the second semiconductor die to form an encapsulated semiconductor device;
the encapsulated semiconductor device comprising back-side electrical contacts of the first semiconductor die and the second semiconductor die exposed at a top surface of the molding material;
a second redistribution layer formed over the encapsulated semiconductor device and electrically connected to the back-side electrical contacts; and
a third semiconductor die attached to the second redistribution layer over each of the first plurality of repeat units.

14. The wafer-level semiconductor structure of claim 13, further comprising through-molding-material vias extending through the molding material to provide electrical connections between the first redistribution layer and the second redistribution layer.

15. The wafer-level semiconductor structure of claim 14, wherein the through-molding-material vias surround a device area where the first semiconductor die and the second semiconductor die are located.

16. The wafer-level semiconductor structure of claim 14, wherein top surfaces of the through-molding-material vias, top surfaces of the back-side electrical contacts, and a top surface of the molding material are coplanar.

17. The wafer-level semiconductor structure of claim 13, wherein each of the first semiconductor die and the second semiconductor die comprise an alignment mark.

18. The wafer-level semiconductor structure of claim 17, wherein the alignment mark is a metallic structure formed within a semiconductor substrate of each of the first semiconductor die and the second semiconductor die.

19. The wafer-level semiconductor structure of claim 13, wherein the molding material comprises a molding compound resin.

20. The wafer-level semiconductor structure of claim 13, further comprising an underfill material formed in spaces between the first semiconductor die and the first redistribution layer.
